(19) United States
(12) Patent Application Publication
(10) Pub. No.: US 2026/0107510 A1
(43) Pub. Date: Apr. 16, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Ta-Chun Lin, Hsinchu (TW); Ming-Heng TSAI, Taipei City (TW); Hong-Chih CHEN, Changhua County (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/911,962

(22) Filed: Oct. 10, 2024

(51) Int. Cl. H01L 29/423; H01L 21/8238; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 84/0167; H10D 84/038; H10D 84/85

(57) ABSTRACT

A method includes forming a first cell unit over a substrate, the first cell unit comprising a first bottom-tire transistor and a first top-tier transistor over the first bottom-tire transistor; forming a second cell unit over the substrate, the second cell unit forming a boundary with the first cell unit and comprising a second bottom-tire transistor and a second top-tier transistor over the second bottom-tire transistor, wherein from a top view, a cell height of the second cell unit is greater than a cell height of the first cell unit in a lengthwise direction of a gate structure of the first top-tier transistor.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate schematic cell array layout diagrams of in accordance with some embodiments of the present disclosure.

FIGS. 1C-1G illustrate schematic cross-sectional views obtained from reference cross-sections A1-A1′, B1-B1′, D1-D1′, E1-E1′, and F1-F1′ in FIGS. 1A and 1B.

FIGS. 2A and 2B illustrate cell array layout diagrams of in accordance with some embodiments of the present disclosure.

FIGS. 2C-2E illustrate schematic cross-sectional views obtained from reference cross-sections A2-A2′, B2-B2′, and C2-C2′ in FIGS. 2A and 2B.

FIG. 3 illustrates an example of a complementary field-effect transistor (CFET) schematic in a three-dimensional view, in accordance with some embodiments of the present disclosure.

FIGS. 4A-21D illustrate schematic views of intermediate stages in the formation of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the complementary field-effect transistor (CFET) technology, transistors (e.g., NMOS and PMOS devices) can be vertically stacked in a gate-all-around (GAA) configuration, allowing for a compact design, enhancing both device performance and integration density. The present disclosure in various embodiments provides small and large cell height devices arranged in a periodic pattern, which in turn leverages the distinct advantages of each cell size. That is, small cells can be used for low power consumption, optimizing energy efficiency across the chip. These smaller cells can be useful in applications of power savings. The larger cells can be used for high-speed performance, providing the processing power for compute-intensive tasks. These larger cells can be useful in applications of requiring rapid data processing and high operational speeds. The periodic placement of these cells can ensure a balanced integration of both power efficiency and speed, allowing for the design of versatile and high-performance semiconductor devices.

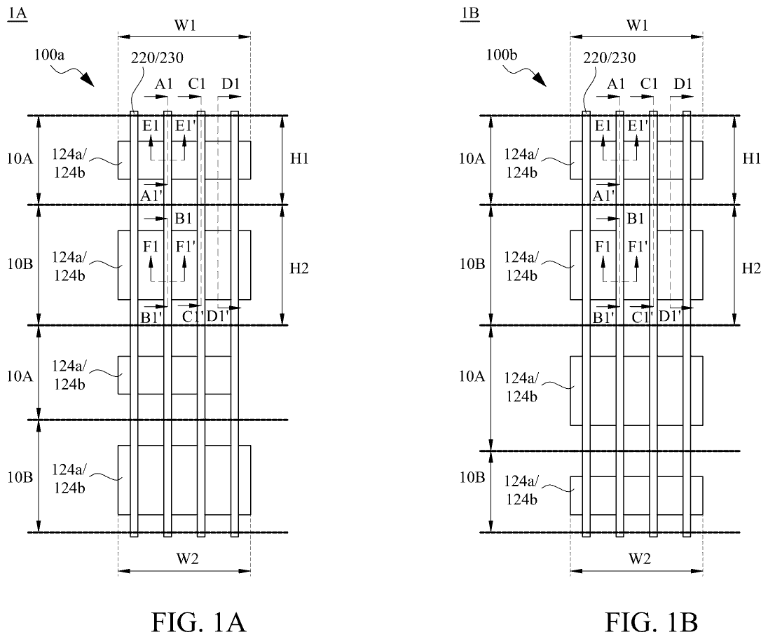

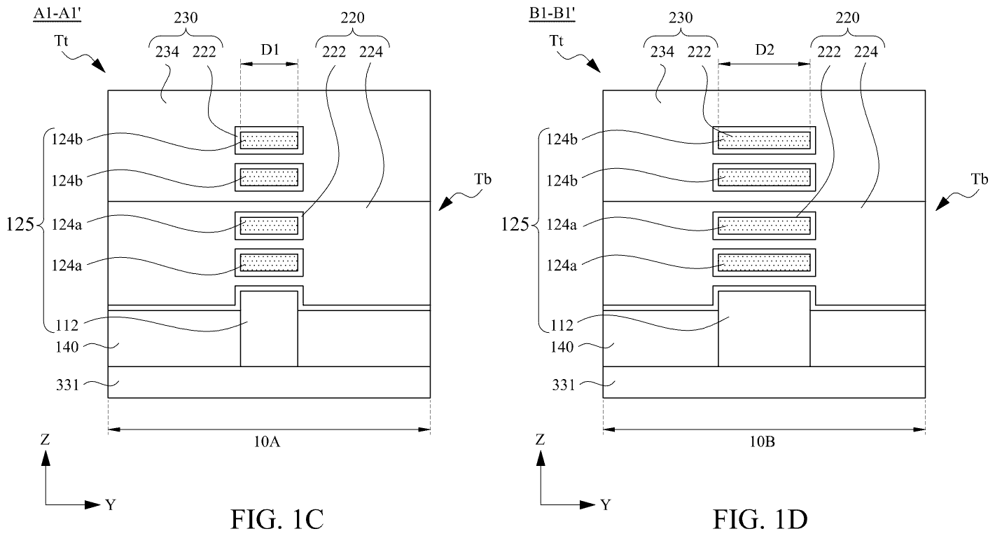

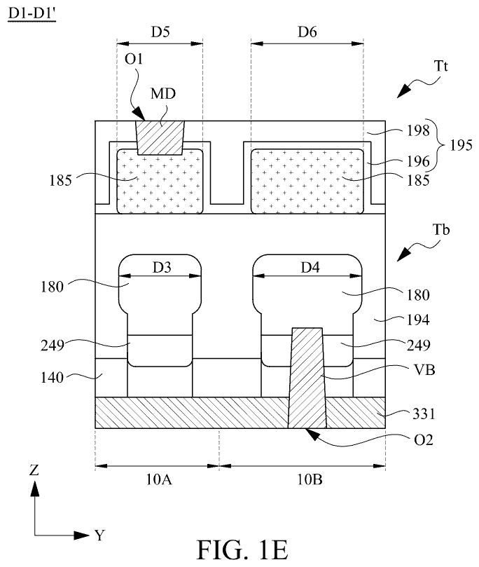

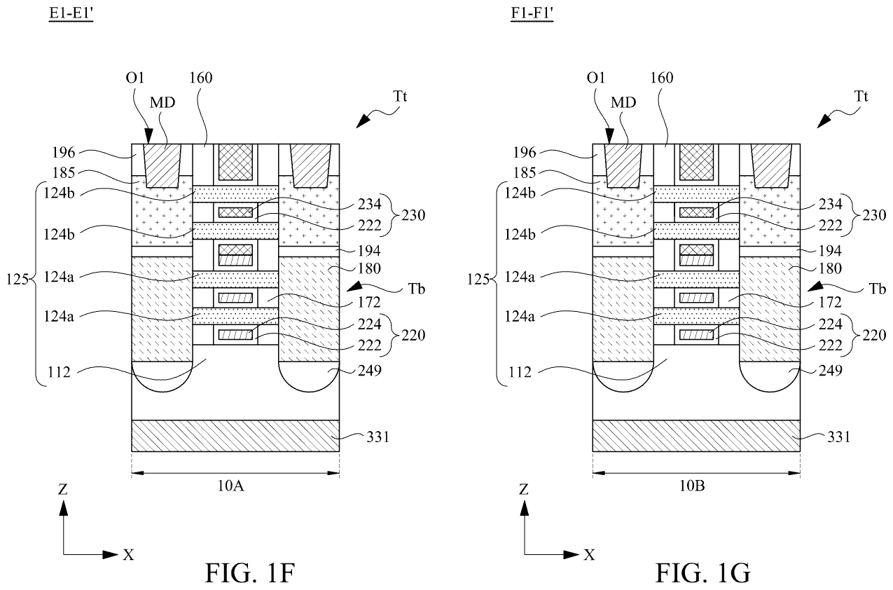

Reference is made to FIGS. 1A-1G. FIGS. 1A and 1B illustrate schematic cell array layout diagrams of in accordance with some embodiments of the present disclosure. FIGS. 1C-1G illustrate schematic cross-sectional views obtained from reference cross-sections A1-A1′, B1-B1′, D1-D1′, E1-E1′, and F1-F1′ in FIGS. 1A and 1B. As shown in FIGS. 1A and 1B, cell units 10A and cell units 10B can be arranged in the same column in the cell array 1A and the cell array 1B. The outer boundary of each of the cell unit 10A and the cell unit 10B is illustrated using dashed lines. In some embodiments, the cell unit 10A and the cell unit 10B can have different cell heights H1 and H2. By way of example but not limiting the present disclosure, the cell height H2 of the cell unit 10B can be greater than the cell height H1 of the cell unit 10A.

The CFET (complementary FET) with hybrid-cell configuration can optimize performance parameters by varying cell heights and transistor configurations. The hybrid-cell configuration in a semiconductor structure can refers to a method where different cell heights (e.g., cell heights H1 and H2) are integrated within the same cell array (e.g., cell arrays 1A/1B) to serve distinct performance, including placing smaller cell unit optimized for low power consumption alongside larger cell unit for high-speed operations. The variation in cell height can allow the semiconductor device to efficiently manage power usage while enhancing performance capabilities. This configuration can enables tailored optimization of power consumption and performance based on the application requirements, potentially improving efficiency and speed in semiconductor devices. In the hybrid-cell configuration, the tallest cell height (e.g., cell height H2 of the cell unit 10B) can vary, being anywhere from about 1.1 to 3.0, such as 1.1, 1.2, 1.4, 1.6, 1.8, 2.2, 2.2, 2.4, 2.6, 2.8, or 3.0, times the height of the smallest cell (e.g., cell height H1 of the cell unit 10A). This means that in a semiconductor layout, the vertical dimension of the largest cells can be at least 10% greater and up to three times greater than that of the smallest cells, allowing for a flexible approach to optimize performance characteristics such as power efficiency and processing speed by tailoring the physical dimensions of the cell units.

The periodic placement of small and large cell height devices within the semiconductor layout to cater to different performance needs (e.g., low power and high speed). As shown in FIG. 1A, the cell array layout can include taller cell unit (e.g., cell unit 10A) periodically placed at intervals among shorter unit cells (e.g., cell unit 10B), allowing for a balanced integration of cell units optimized for different functionalities (e.g., taller cell units for higher speed and shorter cell units for lower power consumption). As shown in FIG. 1B, the cell array layout can alternate between taller and shorter unit cells (e.g., cell units 10B and 10A) in a pattern where two taller cell units (e.g., cell units 10B) can be sandwiched between two shorter cell unit (e.g., cell units 10A). In some embodiments, two shorter cell units can also be arranged be sandwiched between two taller cell units.

In some embodiments, the cell unit 10A and the cell unit 10B can have the same width (e.g., cell width W1 of the cell unit 10A and cell width W2 of the cell unit 10B). In FIGS. 1A and 1B, it should be noted that the configuration of the cell unit 10A and the cell unit 10B is used as an illustration, and not to limit the disclosure. In some embodiments, the column in the cell array 1A/1B may include more or fewer cell units than the layout shown in FIGS. 1A and 1B.

In some embodiments, each logic cell provides a circuit or portion thereof, exemplary functionality provided by the cells includes, but are not limited to NAND, NOR, AND, XOR, XNOR, SACN, inverter, Flip-Flop, latch, and/or other suitable logic or storage functions. For example, the cell unit 10A may have a first one of the logic circuits including inverter, NAND, and NOR circuit schematics and Flip-Flop circuit schematics for NOR and NAND, and the second logic cell unit 10B may have a second one of the logic circuits including inverter, NAND, and NOR circuit schematics and Flip-Flop circuit schematics for NOR and NAND. In some embodiments, the cell unit 10B may have a different circuit schematic than the cell unit 10A. By way of example but not limiting the present disclosure, the cell unit 10A may have a NAND circuit, and the cell unit 10B may have an inverter.

Semiconductor structures 100a and 100b shown in FIGS. 1A-1G can be complementary field effect transistor, where transistor can be vertically stacked in a gate-all-around (GAA) configuration, allowing for better space utilization and electrical properties. The semiconductor structure 100a/100b can include top-tier transistors Tt formed over bottom-tier transistors Tb. The bottom-tier transistor Tb can include the channel layers 124a, the first source/drain epitaxial structures 180 on opposite sides of the channel layers 124a and connected to the channel layers 124a, and the gate structure 220 wrapping around the channel layers 124a. The gate structure 220 can include a lower portion of the high-k gate dielectric layer 222 and the gate electrode layer 224. The top-tier transistor Tt can include the channel layers 124b, the second source/drain epitaxial structures 185 on opposite sides of the channel layers 124b and connected to the channel layers 124b, and a (metal) gate structure 230 wrapping around the channel layers 124b. The gate structure 230 can include an upper portion of the high-k gate dielectric layer 222 and the gate electrode layer 234.

In some embodiments, the bottom-tier transistors Tb can be a first conductivity type, and the e top-tier transistors Tt can be a second conductivity type opposite to the first conductivity type. By way of example but not limiting the present disclosure, the bottom-tier transistors Tb can be p-type transistors, and the top-tier transistors Tt can be n-type transistors. In some embodiments, the bottom-tier transistors Tb can be n-type transistors, and the top-tier transistors Tt can be p-type transistors. In some embodiments, the bottom-tier transistors Tb can be a same conductivity type as the top-tier transistors Tt.

In some embodiments, a dimension D1 (see FIG. 1C) of the epitaxial layer 122a/122b in the cell unit 10A along the Y-direction is different than a dimension D2 (see FIG. 1D) of the epitaxial layer 122a/122b in the cell unit 10B along the Y-direction. By way of example but not limiting the present disclosure, the dimension D2 can vary, being anywhere from about 1.1 to 3.0, such as 1.1, 1.2, 1.4, 1.6, 1.8, 2.2, 2.2, 2.4, 2.6, 2.8, or 3.0, times the dimension D1. In some embodiments, a dimension D3 (see FIG. 1E) of the first source/drain epitaxial structure 180 in the cell unit 10A along the Y-direction is different than a dimension D4 (see FIG. 1E) of the first source/drain epitaxial structure 180 in the cell unit 10B along the Y-direction. By way of example but not limiting the present disclosure, the dimension D4 can vary, being anywhere from about 1.1 to 3.0, such as 1.1, 1.2, 1.4, 1.6, 1.8, 2.2, 2.2, 2.4, 2.6, 2.8, or 3.0, times the dimension D3. In some embodiments, a dimension D5 of the second source/drain epitaxial structure 185 in the cell unit 10A along the Y-direction is different than a dimension D6 of the second source/drain epitaxial structure 185 in the cell unit 10B along the Y-direction. By way of example but not limiting the present disclosure, the dimension D6 can vary, being anywhere from about 1.1 to 3.0, such as 1.1, 1.2, 1.4, 1.6, 1.8, 2.2, 2.2, 2.4, 2.6, 2.8, or 3.0, times the dimension D5.

In some embodiments, a protruding portion 112 can be formed to underlay the epitaxial layers 122a and 122b. Isolation structures 140 can be formed to surround the protruding portion 112. Gate spacers 160 can be formed on sidewalls of the gate structure 230. Inner dielectric spacers 172 can be formed to isolate the gate structures 220 and 230 from the first and second source/drain epitaxial structures 180 and 185. Dielectric layers 249 can be formed on bottoms of the first and second source/drain epitaxial structures 180 and 185. An interlayer dielectric (ILD) layer 194 can be formed to sandwich between the first source/drain epitaxial structure 180 and the second source/drain epitaxial structures 185 to electrically isolate the first source/drain epitaxial structure 180 from the second source/drain epitaxial structure 185. An ILD layer 198 can be formed over the second source/drain epitaxial structures 185. In some embodiments, a contact etch stop layer (CESL) 196 can be also formed to sandwich between the second source/drain epitaxial structures 185 and the ILD layer 198. Source/drain contacts MD can be formed to pass through the ILD layer 198 and the CESL layer 196 to land on the second source/drain epitaxial structure 185. A back-side dielectric layer 331 can be formed over the back-side 110b of the substrate 110. Back-side source/drain contacts VB can be formed to pass through the back-side dielectric layer 331, the dielectric layer 249, and the protruding portion 112 to the first source/drain epitaxial structure 180.

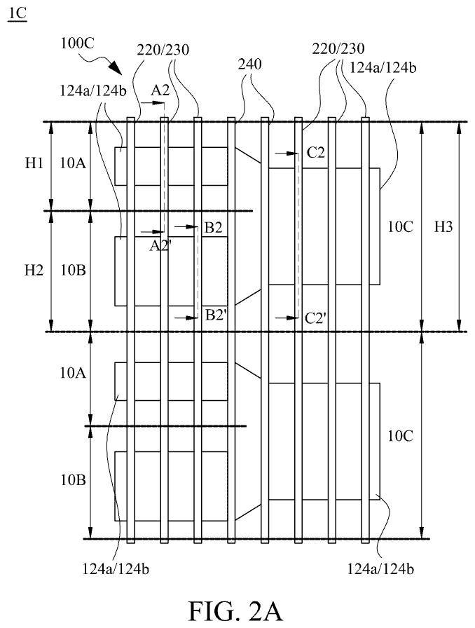

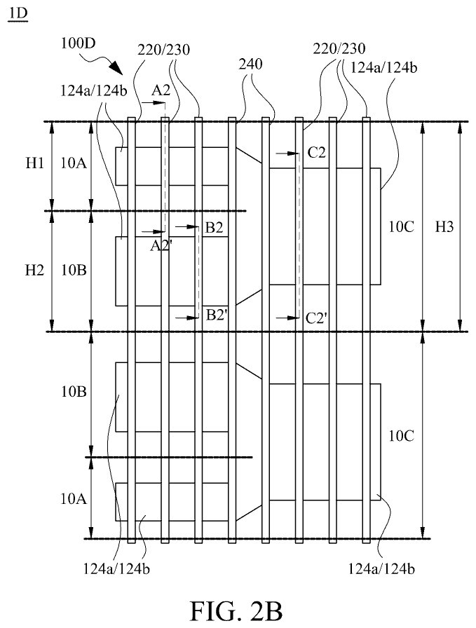

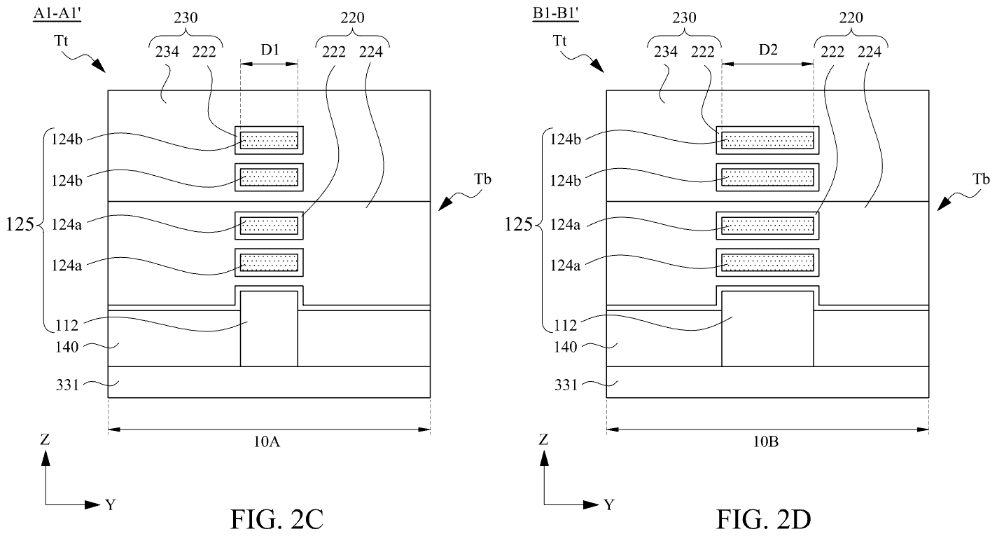

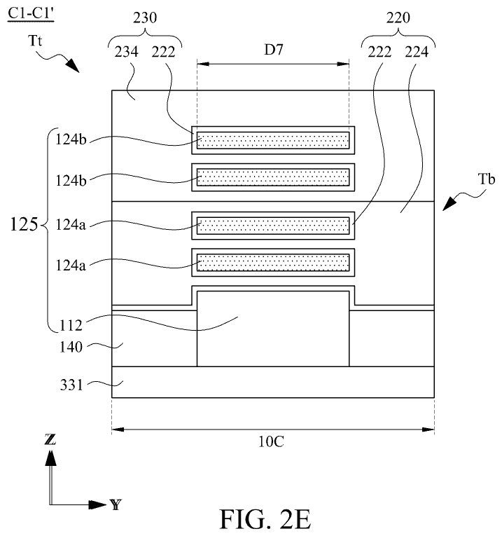

Reference is made to FIGS. 2A-2E. FIGS. 2A and 2B illustrate layout diagrams of cell arrays 1C and 1D of in accordance with some embodiments of the present disclosure. FIGS. 2C-2E illustrate schematic cross-sectional views obtained from reference cross-sections A2-A2′, B2-B2′, and C2-C2′ in FIGS. 2A and 2B. While FIGS. 2A-2E show embodiments of the semiconductor structures 100c and 100d with a different profile than the semiconductor structure 100a and 100b in FIGS. 1A-2E. In addition, the present disclosure may repeat reference numerals and/or letters in the various examples. This repetition is for the purpose of simplicity and clarity and does not in itself dictate a relationship between the various embodiments and/or configurations discussed.

The distinction between the semiconductor structures illustrated in FIGS. 1A-1G and those in FIGS. 2A-2E is the inclusion of cell unit 10C in FIGS. 2A-2E. The cell unit 10C can serves as a connector between hybrid cells (i.e., cell units 10A and 10B). As illustrated in FIGS. 2A and 2B, the cell unit 10C can have a cell height H3 that may combine the cell heights of cell units 10A and 10B, making the cell height H3 the sum of the cell heights H1 and H2. Moreover, the dimension of the active region (e.g., epitaxial layers 124a and 124b) along the Y-direction in the cell unit 10C, can be larger compared to those in the cell units 10A and 10B, which in turn facilitates enhanced connectivity and interaction between the hybrid cell units 10A and 10B, providing a structural and functional bridge that enhances the overall integration and performance of the semiconductor device. Specifically, a dimension D7 of the epitaxial layer 122a/122b in the cell unit 10C along the Y-direction is different than the dimension D1/D2 of the epitaxial layer 122a/122b in the cell unit 10A/10B along the Y-direction. By way of example but not limiting the present disclosure, the dimension D7 can vary, being anywhere from about 1.1 to 3.0, such as 1.1, 1.2, 1.4, 1.6, 1.8, 2.2, 2.2, 2.4, 2.6, 2.8, or 3.0, times the dimension D1/D2.

In some embodiments, the isolation between cell units 10A, 10B, and 10C can be achieved using one or more continuous poly on oxide definition (CPODE) patterns 240. These CPODE patterns 240 can be line patterns that extend in parallel with the gate structures 220 and 230. As illustrated in FIGS. 2A and 2B, the layout can include transitions featuring two CPODE patterns 240 between the cell units 10A and 10C, as well as between the cell units 10B and 10C. The CPODE patterns 240 can maintain a spacing of 1-CPP (gate pitch) consistent with the gate structures 220 and 230. In some embodiments, the transitions between these cell units (i.e., cell units 10A, 10B, and 10C) might incorporate more than two CPODE patterns 240, where the pitch between adjacent CPODE lines can exceed the gate pitch of gate structures 220 and 230. This variation can be used to adjust the isolation characteristics and electrical performance. Additionally, some configuration may employ a combination of poly on oxide definition (PODE) and CPODE patterns for enhanced isolation. The materials used for CPODE patterns can including silicon nitride (SiN), silicon dioxide (SiO₂), silicon oxynitride (SiON), silicon carbide nitride (SiCN), silicon carbonitride oxide (SiCON), silicon carbon oxide (SiCO), and high-k materials like hafnium Oxide (HfO) and aluminum oxide (AlO), as well as multiple layer composites.

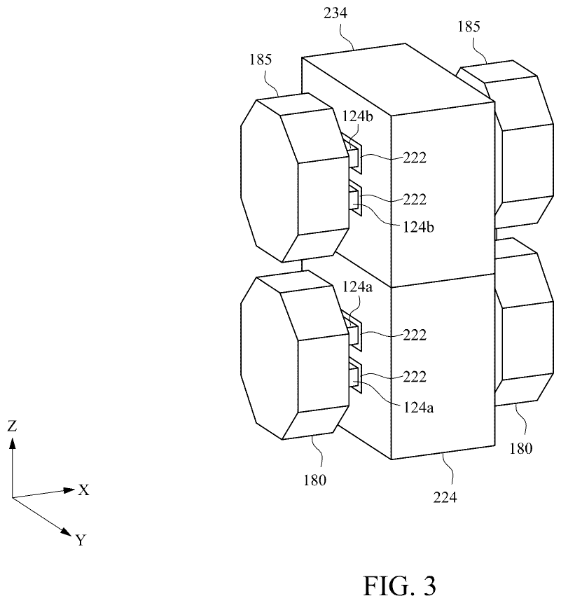

Reference is made to FIG. 3. FIG. 3 illustrates an example of a complementary field-effect transistor (CFET) schematic in a three-dimensional view, in accordance with some embodiments of the present disclosure. The CFET schematic shown in FIG. 3, featuring vertically stacked or closely placed NMOS and PMOS devices, can be integrated into the semiconductor structures depicted in FIGS. 1A-2E. The CFETs include multiple vertically stacked nanostructure-FETs. For example, a CFET may include a lower nanostructure-FET of a first device type (e.g., n-type/p-type) and an upper nanostructure-FET of a second device type (e.g., p-type/n-type) that is opposite (or the same as) the first device type. Specifically, the CFET may include a lower PMOS transistor and an upper NMOS transistor, or the CFET may include a lower NMOS transistor and an upper PMOS transistor. Each of the nanostructure-FETs include epitaxial layers 124a and 124b as channel regions. The epitaxial layers 124a and 124b may be nanosheets, nanowires, or the like. A high-k dielectric layer 222 is formed along top surfaces, sidewalls, and bottom surfaces of the epitaxial layer 124a/124b. Metal gate electrodes 224 and 234 are formed over the high-k dielectric layer 222 and around the epitaxial layer 124a/124b. Source/drain epitaxial structures 180/185 are disposed at opposing sides of the metal gate electrode 224/234. Source/drain epitaxial structure 180/185 may refer to a source or a drain, individually or collectively dependent upon the context.

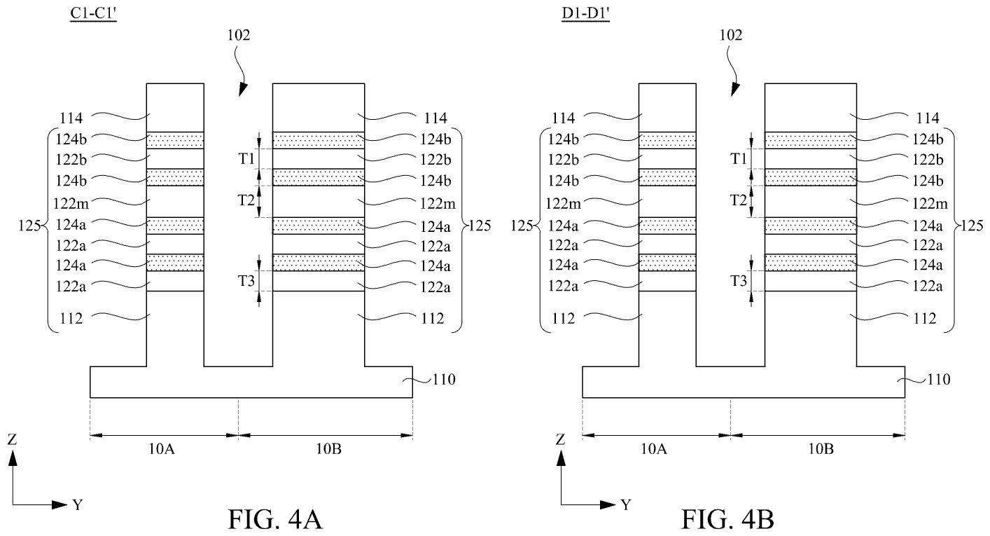

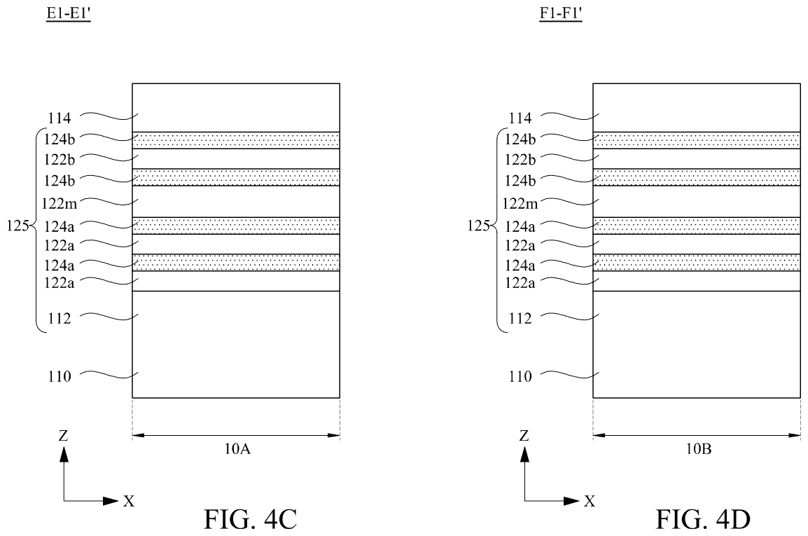

Reference is made to FIGS. 4A-21D. FIGS. 4A-21D illustrate schematic views of intermediate stages in the formation of a semiconductor structure in accordance with some embodiments of the present disclosure. FIGS. 4A, 5A, 6A, 7A, 8A, 9A, 10A, 11A, 12A, 13A, 14A, 15A, 16A, 17A, 18A, 19A, 20A, and 21A illustrate schematic cross-sectional views obtained from reference cross-sections C1-C1′ in FIGS. 1A and 1B. FIGS. 4B, 5B, 6B, 7B, 8B, 9B, 10B, 11B, 12B, 13B, 14B, 15B, 16B, 17B, 18B, 19B, 20B, and 21B illustrate schematic cross-sectional views obtained from reference cross-sections D1-D1′ in FIGS. 1A and 1B. FIGS. 4C, 5C, 6C, 7C, 8C, 9C, 10C, 11C, 12C, 13C, 14C, 15C, 16C, 17C, 18C, 19C, 20C, and 21C illustrate schematic cross-sectional views obtained from reference cross-sections E1-E1′ in FIGS. 1A and 1B. FIGS. 4D, 5D, 6D, 7D, 8D, 9D, 10D, 11D, 12D, 13, 14D, 15D, 16D, 17D, 18D, 19D, 20D, and 21D illustrate schematic cross-sectional views obtained from reference cross-sections F1-F1′ in FIGS. 1A and 1B. It is understood that additional operations can be provided before, during, and after the processes shown by FIGS. 4A-21D, and some of the operations described below can be replaced or eliminated, for additional embodiments of the method. The order of the operations/processes may be interchangeable.

Reference is made to FIGS. 4A-4D. An epitaxial stack is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer.

The epitaxial stack includes epitaxial layers 122a, 122b, 122m of a first composition interposed by epitaxial layers 124a and 124b of a second composition. The first and second compositions can be different. In some embodiments, the epitaxial layers 122a, 122b, and 122m may be made of SiGe, and the epitaxial layers 124a and 124b may be made of silicon (Si). However, other embodiments are possible including those that provide for a first composition and a second composition having different etch selectivity.

The epitaxial layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the epitaxial layers 124a and 124b to define a channel or channels of a device is further discussed below. In FIGS. 4A-4D, the epitaxial layers 124b are disposed above the epitaxial layers 124a. It is noted that two layers of the epitaxial layers 124a and two layers of the epitaxial layers 124b are arranged as illustrated in FIGS. 4A-4D, which is for illustrative purposes only and not intended to be limiting beyond what is specifically recited in the claims. It can be appreciated that any number of epitaxial layers can be formed in the epitaxial stack; the number of layers depending on the desired number of channels regions for the transistor. In some embodiments, the number of each of the epitaxial layers 124a and 124b can be between 1 and 10, such as 1, 2, 3, 4, 5, 6, 7, 8, 9, or 10. In some embodiments, the epitaxial layers 124a can be have a different number than the epitaxial layers 124b. In some embodiments, the epitaxial layers 124a can be made of a different material than the epitaxial layers 124b. In some embodiments, the epitaxial layers 124a can have a vertical dimension T3 (e.g., thickness/height) different than a vertical dimension T1 of the epitaxial layers 124b. By way of example but not limiting the present disclosure, a vertical dimension difference between the epitaxial layers 124a and 124b can be in a range from about 0.5 to 5 nm, such as 0.5, 1, 1.5, 2, 2.5, 3, 3.5, 4, 4.5, or 5 nm. In some embodiments, the vertical dimensions T1 and T3 of the epitaxial layers 122a and 122b can be substantially the same. In some embodiments, a distance (or space) between adjacent two of the epitaxial layers 124a can be different than a distance (or space) between adjacent two of the epitaxial layers 124a. By way of example but not limiting the present disclosure, a distance difference between the epitaxial layers 124a and 124b can be in a range from about 0.5 to 5nm, such as 0.5, 1, 1.5, 2, 2.5, 3, 3.5, 4, 4.5, or 5 nm.

The epitaxial layers 122a are interposed by the epitaxial layers 124a, the epitaxial layers 122b are interposed by the epitaxial layers 124b, and the epitaxial layer 122m is between the epitaxial layers 124a and 124b. In some embodiments, the epitaxial layer 122m has a vertical dimension T2 (e.g., thickness/height) greater than the vertical dimensions T1 and T3 of the epitaxial layers 124a and 124b. In some embodiments, the epitaxial layer 122m can have a greater germanium atomic concentration than the epitaxial layers 122a and 122b.

As described in more detail below, the epitaxial layers 124a and 124b may serve as channel region(s) for a subsequently-formed semiconductor device and the thickness is chosen based on device performance considerations. The epitaxial layers 122a, 122b, and 122m in channel regions(s) may eventually be removed and serve to define a vertical distance between adjacent channel region(s) for a subsequently-formed multi-gate device and the thickness is chosen based on device performance considerations. Accordingly, the epitaxial layers 122a, 122b, and 122m may also be referred to as sacrificial layers, and epitaxial layers 124a and 124b may also be referred to as channel layers. In some embodiments, the epitaxial layers 124a and 124b can be interchangeably referred to as channel regions or channel patterns.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124a and 124b include the same material as the substrate 110. In some embodiments, the epitaxial layers 122a, 122b, 122m, 124a, and 124b can include a different material than the substrate 110. As stated above, in at least some examples, the epitaxial layers 122a, 122b, and 122m can include an epitaxially grown silicon germanium (SiGe) layer and the epitaxial layers 124a and 124b include an epitaxially grown silicon (Si) layer. Alternatively, in some embodiments, either of the epitaxial layers 122a, 122b, 122m, 124a, and 124b may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the epitaxial layers 122a, 122b, 122m, 124a, and 124b may be chosen based on providing differing oxidation and/or etching selectivity properties.

In FIGS. 4A-4D, at least one fin structure 125 extending from the substrate 110 can be formed. In some embodiments, the fin structure 125 can include a protruding portion 112 formed from the substrate 110 and portions of each of the epitaxial layers of the epitaxial stack including epitaxial layers 122a, 122b, 122m and 124a, 124b. The fin structure 125 may be fabricated using suitable processes including double-patterning or multi-patterning processes on the epitaxial stack. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin structure 125 by etching the epitaxial stack through mask layers 114. The etching process can include dry etching, wet etching, reactive ion etching (RIE), and/or other suitable processes. Subsequently, the etch process can form trenches 102 into the substrate 110, thereby leaving the fin structure 125. Numerous other embodiments of methods to form the fin structure 125 on the substrate 110 may also be used including, for example, defining the fin region (e.g., by mask or isolation regions) and epitaxially growing the epitaxial stack in the form of the fin structure 125. In some embodiments, the dimension D1 of the epitaxial layers 122a, 122b, 122m, 124a, or 124b in the cell unit 10A along the Y-direction is different than the dimension D2 of the epitaxial layers 122a, 122b, 122m, 124a, or 124b in the cell unit 10B along the Y-direction.

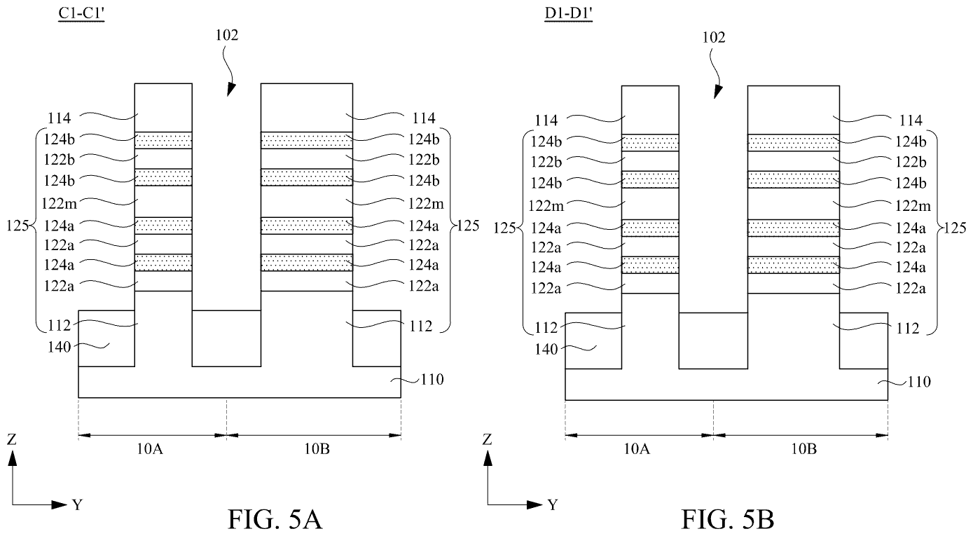

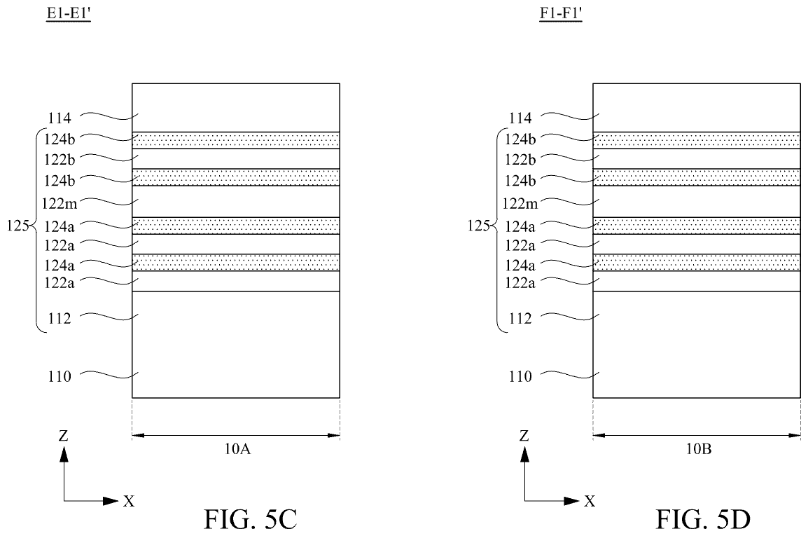

Reference is made to FIGS. 5A-5D. Isolation structures 140 can be formed to surround the fin structure 125. The isolation structures 140 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 140 may also include a dielectric material over the liner oxide, and the dielectric material may be formed using flowable chemical vapor deposition (FCVD), spin-on coating, or the like. Subsequently, the isolation structures 140 are recessed, so that the top portion of the fin structure 125 protrudes higher than the top surfaces of the neighboring isolation structures 140. The etching may be performed using a dry etching process, wherein NH₃ and NF₃ are used as the etching gases. During the etching process, plasma may be generated. Argon may also be included. In accordance with alternative embodiments of the present disclosure, the recessing of the isolation structures 140 is performed using a wet etch process. The etching chemical may include diluted HF, for example.

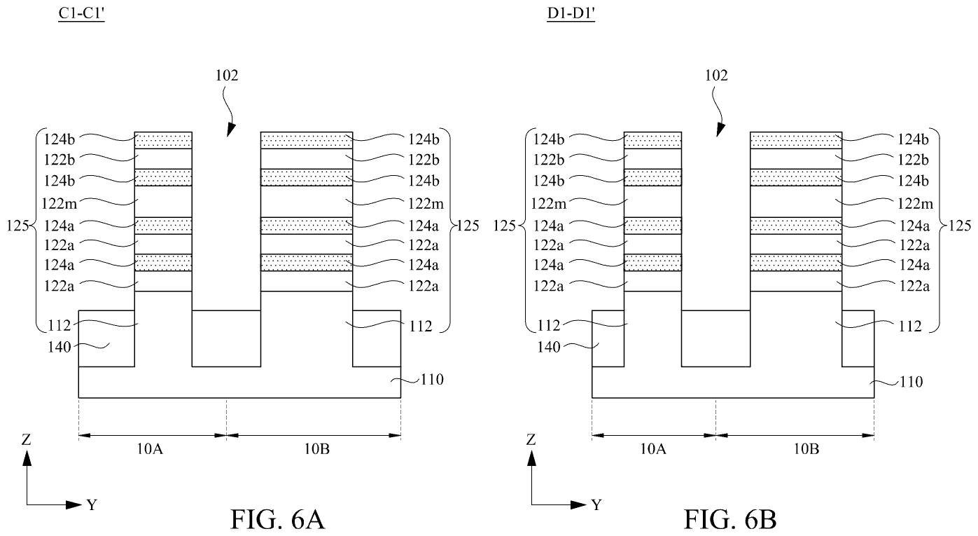

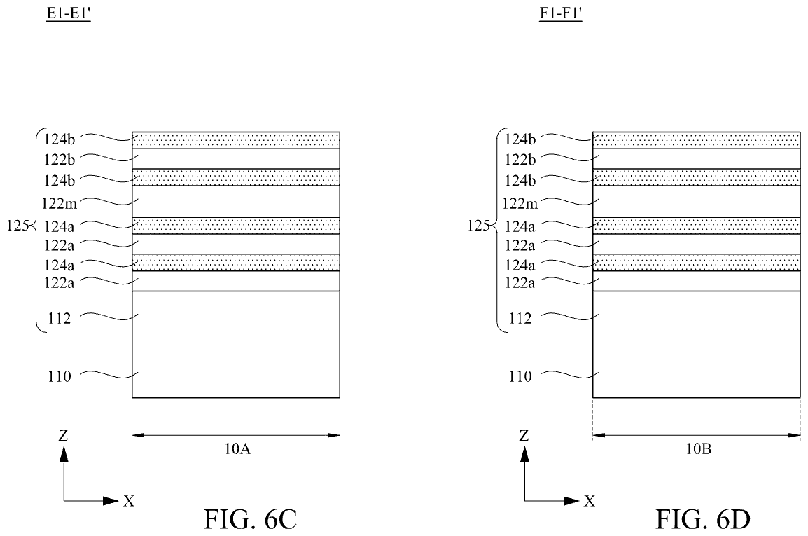

Reference is made to FIGS. 6A-6D. The mask layers 114 can be removed. In some embodiments, the mask layer 114, if formed of silicon nitride, may be removed by a wet process using hot H₃PO_{4.} In some embodiments, the mask layer 114, if formed of silicon oxide, may be removed using diluted HF. In some embodiments, a cleaning step may be optionally performed to remove a native oxide of the semiconductor substrate 110. The cleaning may be performed using diluted hydrofluoric (HF) acid, by way of example and not limitation.

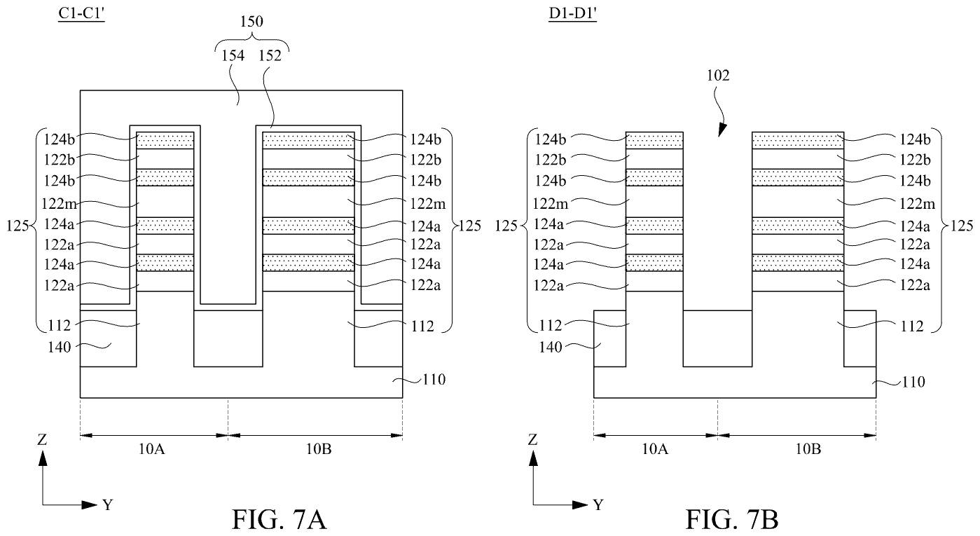

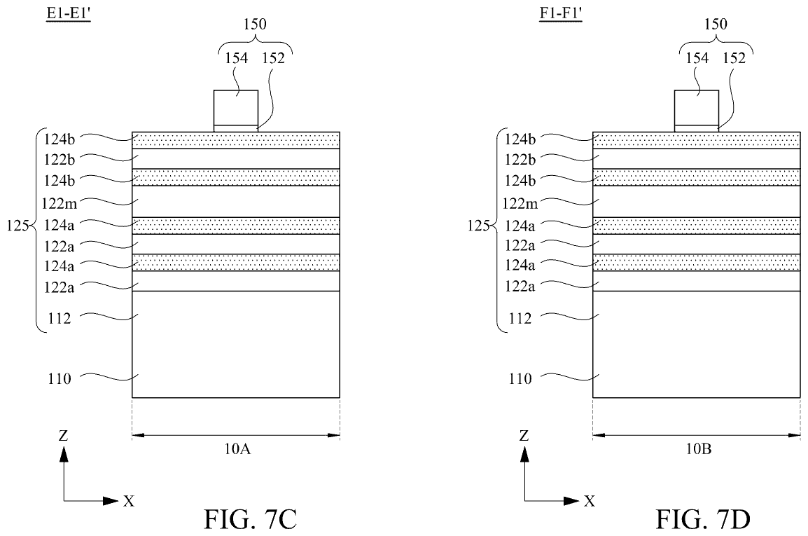

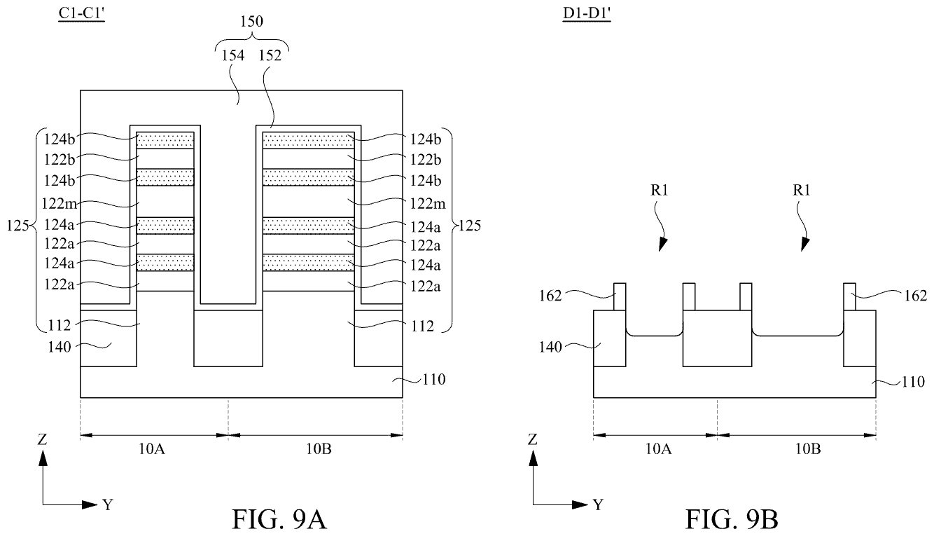

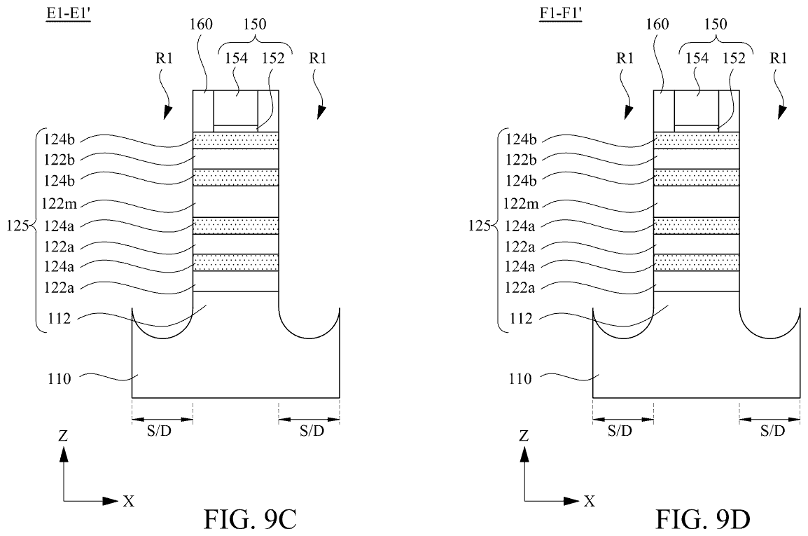

Reference is made to FIGS. 7A-7D. At least one dummy gate structure 150 can be formed over the substrate 110 and is partially disposed over the fin structure 125. The portion of the fin structure 125 underlying the dummy gate structure 150 may be referred to as the channel region. The dummy gate structure 150 may also define source/drain regions S/D (labeled in FIGS. 9C and 9D) of the fin structure 125, for example, the regions of the fin structure 125 adjacent and on opposing sides of the channel region.

Dummy gate formation operation forms a dummy gate dielectric layer, a dummy gate electrode layer and a hard mask which may include multiple layers (e.g., an oxide layer and a nitride layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, a dummy gate structure 150 including a dummy gate dielectric layer 152 and a dummy gate electrode layer 154 can be formed. In some embodiments, the dummy gate structure 150 can be interchangeably referred to a dummy gate, a dummy gate pattern, a dummy gate strip, an isolation structure, or a dielectric gate.

In some embodiments, the dummy gate dielectric layer 152 may be made of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multi-layer structure including a plurality of dielectric layers. In some embodiments, the dummy gate dielectric layer 152 may be made of high-k dielectric materials, such as metal oxides, transition metal-oxides, or the like. Examples of the high-k dielectric material include, but are not limited to, hafnium oxide (HfO₂), hafnium silicon oxide (HfSiO), hafnium tantalum oxide (HfTaO), hafnium titanium oxide (HfTiO), hafnium zirconium oxide (HfZrO), zirconium oxide, titanium oxide, aluminum oxide, hafnium dioxide-alumina (HfO₂—Al₂O₃) alloy, or other applicable dielectric materials. The dummy gate dielectric layer 152 may be formed by a deposition processes, such as chemical vapor deposition (CVD), physical vapor deposition (PVD), atomic layer deposition (ALD), plasma enhanced CVD (PECVD) or other suitable techniques. In some embodiments, the dummy gate electrode layer 154 may include polycrystalline-silicon (poly-Si), poly-crystalline silicon-germanium (poly-SiGe), metallic nitrides, metallic silicides, metallic oxides, or metals. In some embodiments, the dummy gate electrode layer 154 may include a metal-containing material such as TiN, TaN, TaC, Co, Ru, Al, combinations thereof, or multi-layers thereof. The dummy gate electrode layer 154 may be deposited by CVD, physical vapor deposition (PVD), sputter deposition, or other techniques suitable for depositing conductive materials.

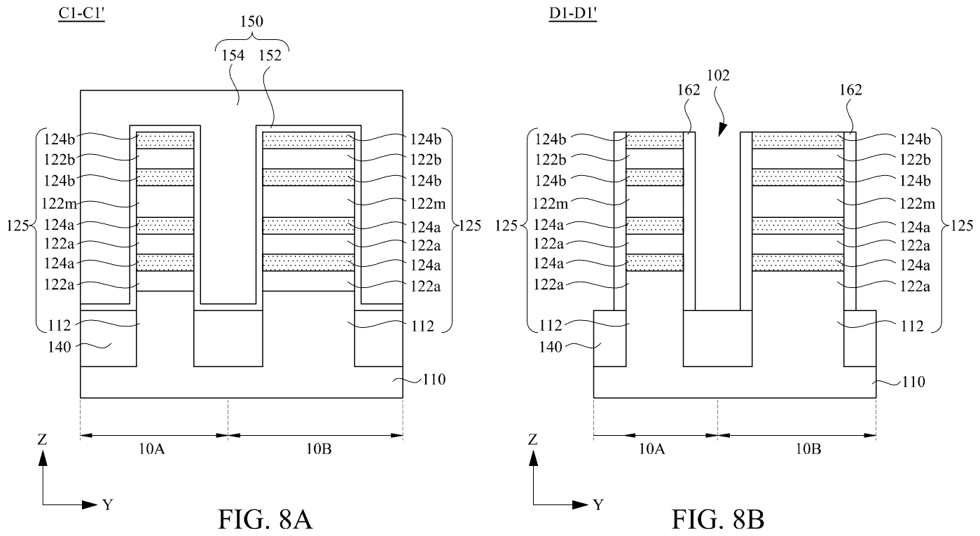

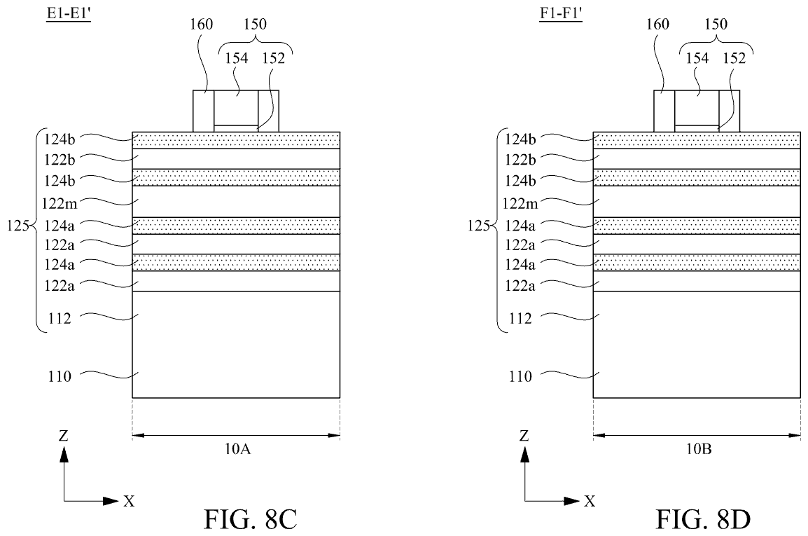

Reference is made to FIGS. 8A-8D. Gate spacers 160 (see FIGS. 8C and 8D) and fin spacers 162 (see FIG. 8B) can be formed on sidewalls of the dummy gate structure 150 as shown in FIGS. 8C and 8D, and on sidewalls of the fin structure 125 as shown in FIG. 8B. For example, a spacer material layer is deposited on the substrate 110. The spacer material layer may be a conformal layer that is subsequently etched back to form gate sidewall spacers. In the illustrated embodiment, a spacer material layer is disposed conformally on top and sidewalls of the dummy gate structure 150 and the fin structure 125. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gate structure 150 and the fin structure 125 using suitable deposition processes. An anisotropic etching process is then performed on the deposited spacer material layer to expose portions of the fin structure 125 not covered by the dummy gate structure 150 (e.g., over the source/drain regions of the fin structure 125). Portions of the spacer material layer directly above the dummy gate structure 150 and the fin structure 125 may be completely removed by this anisotropic etching process. Portions of the spacer material layer on sidewalls of the dummy gate structure 150 and the fin structure 125 may remain, forming gate sidewall spacers, which are denoted as the gate spacers 160 and the fin spacers 162, for the sake of simplicity.

Reference is made to FIGS. 9A-9D. Exposed portions of the fin structure 125 that extend laterally beyond the gate spacers 160 (e.g., in source/drain regions S/D of the fin structure 125) can be etched by using, for example, an anisotropic etching process that uses the dummy gate structure 150 and the gate spacers 160 as an etch mask, resulting in recesses R1 into the fin structure 125. After the anisotropic etching, end surfaces of the epitaxial layers 122a, 122b, 122m, and the epitaxial layers 124a, 124b and respective outermost sidewalls of the gate spacers 160 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. When forming recess R1, the anisotropic etching process may also performed that affects the fin spacers 162, which in turn reduces the size of the fin spacers 162 and positions them on both sides of the recess R1. As a result, the fin spacers 162, initially sized to match the fin structure 125, become smaller due to the anisotropic etching, leaving the fin spacers 162 positioned to align with the recess R1.

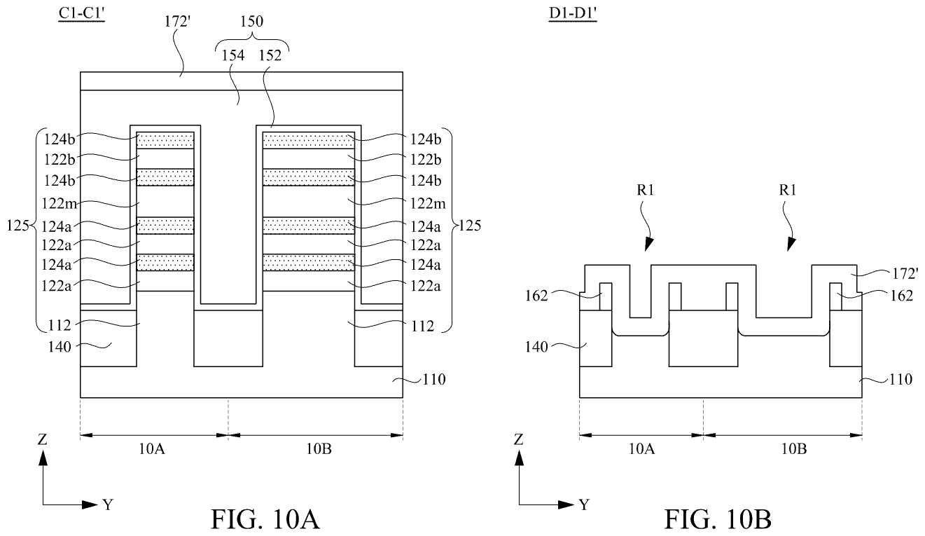

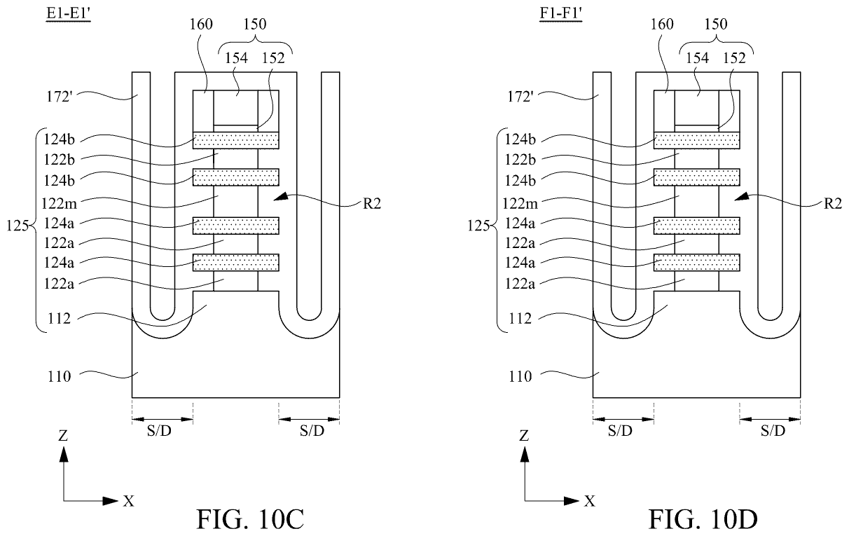

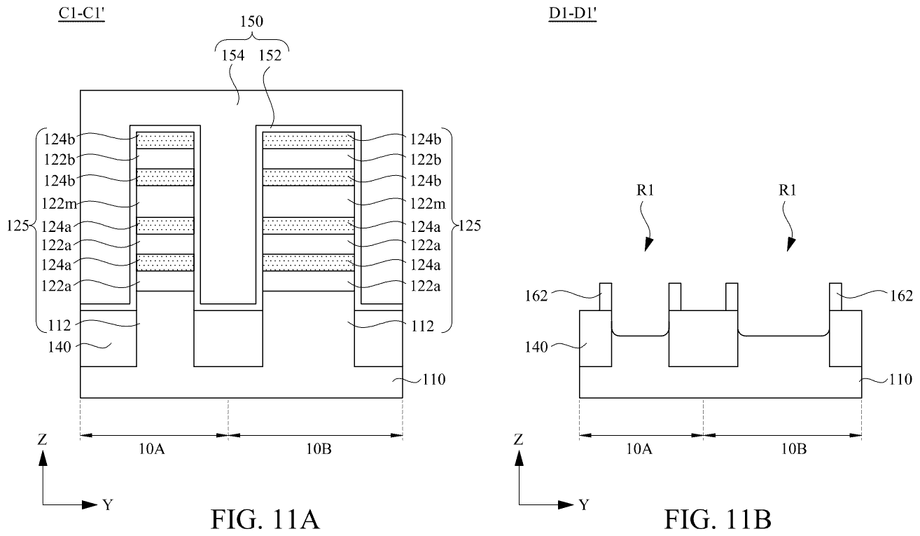

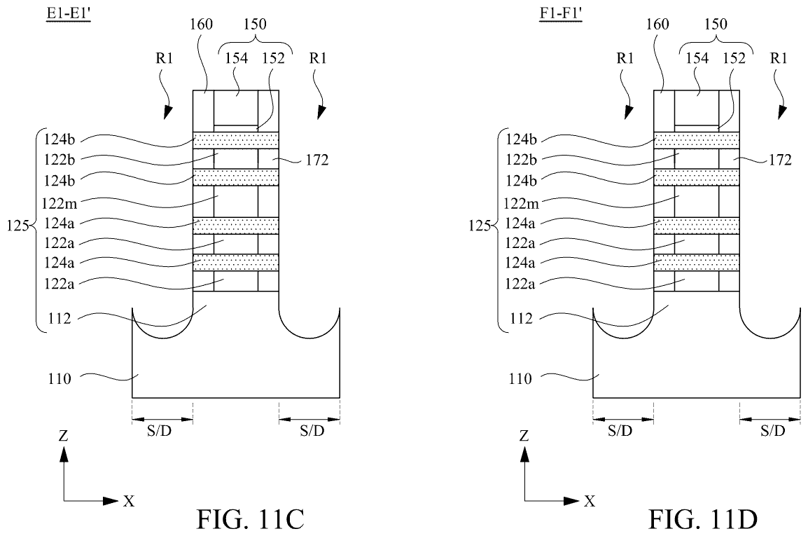

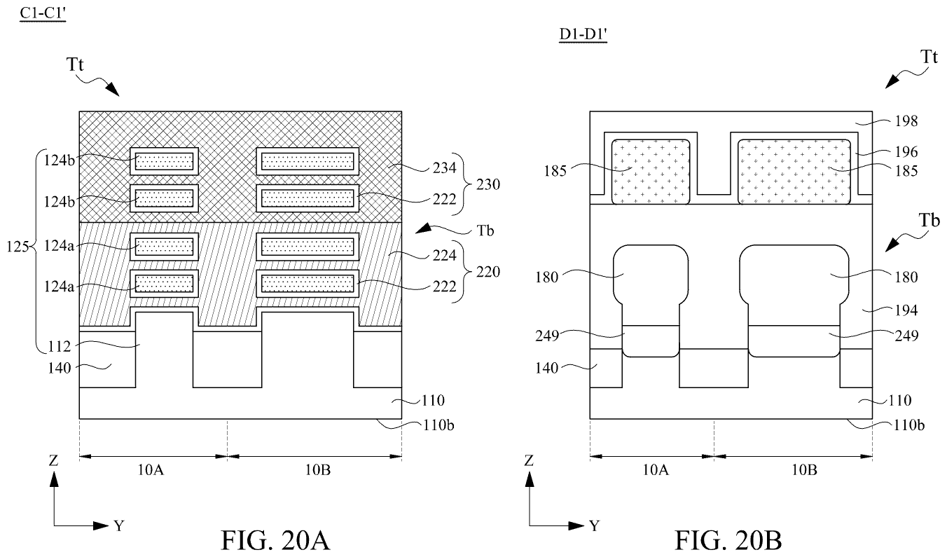

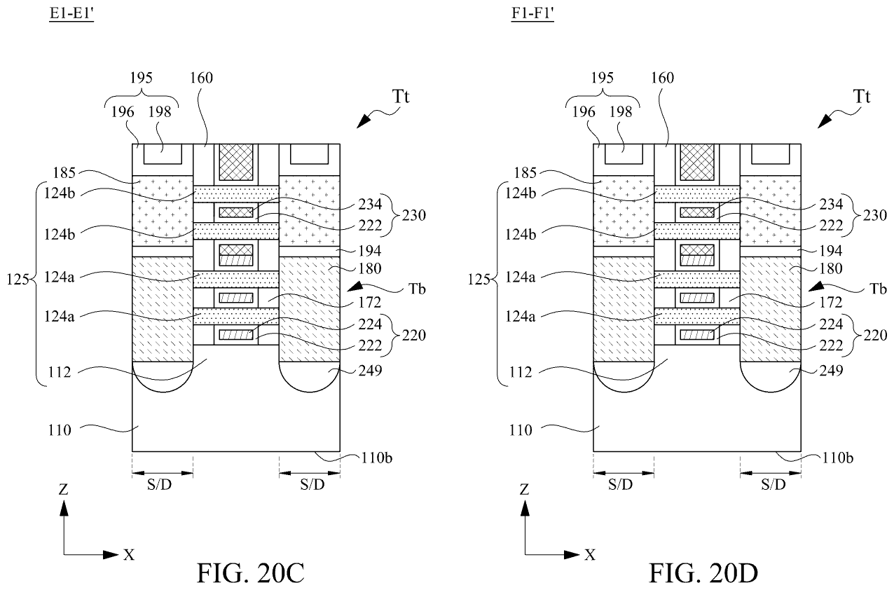

Reference is made to FIGS. 10A-11D. Inner dielectric spacers 172 (see FIGS. 11C and 11D) can be formed to isolate metal gates (see FIGS. 20C and 20D) from source/drain epitaxial structures (see FIGS. 20C and 20D) formed in subsequent processing. Specifically, as shown in FIGS. 10A-10D, epitaxial layers 122a, 122b, and 122m are laterally or horizontally recessed by using suitable etch techniques, resulting in lateral recesses R2 (see FIGS. 10C and 10D). This operation may be performed by using a selective etching process. By way of example and not limitation, the epitaxial layers 122a, 122b, and 122m can include SiGe, and the epitaxial layers 124a and 124b can include silicon, allowing for the selective etching of the epitaxial layers 122a, 122b, and 122m. In some embodiments, the selective dry etching etches SiGe at a faster etch rate than it etches Si. As a result, the epitaxial layers 124a and 124b laterally extend past opposite end surfaces of the epitaxial layers 122a, 122b, and 122m.

Subsequently, inner dielectric spacers 172 can be filled in the recesses R2. For example, spacer material layers 172′ are formed to fill the recesses R2 left by the lateral etching of the epitaxial layers 122a, 122b, and 122m discussed above. The spacer material layer 172′ may be a low-k dielectric material, such as SiO₂, SiN, SiC, SiON, SiCN, or SiOCN, and may be formed by a suitable deposition method, such as ALD. In some embodiments, the spacer material layer 172′ is intrinsic or un-doped with impurities. The spacer material layer 172′ can be formed using CVD, including LPCVD and PECVD, PVD, ALD, or other suitable processes.

As shown in FIGS. 11A-11D, after the deposition of the spacer material layer 172′, an anisotropic etching process can be performed to trim the deposited spacer material layer 172′, such that portions of the deposited spacer material layer 172′ that fill the recesses R2 are left. After the trimming process, the remaining portions of the deposited spacer material are denoted as inner dielectric spacers 172 in the recesses R2.

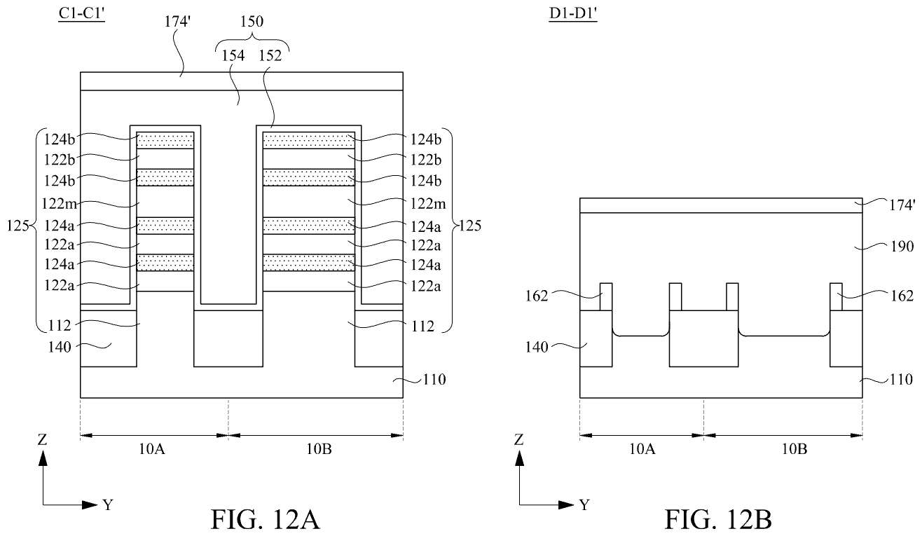

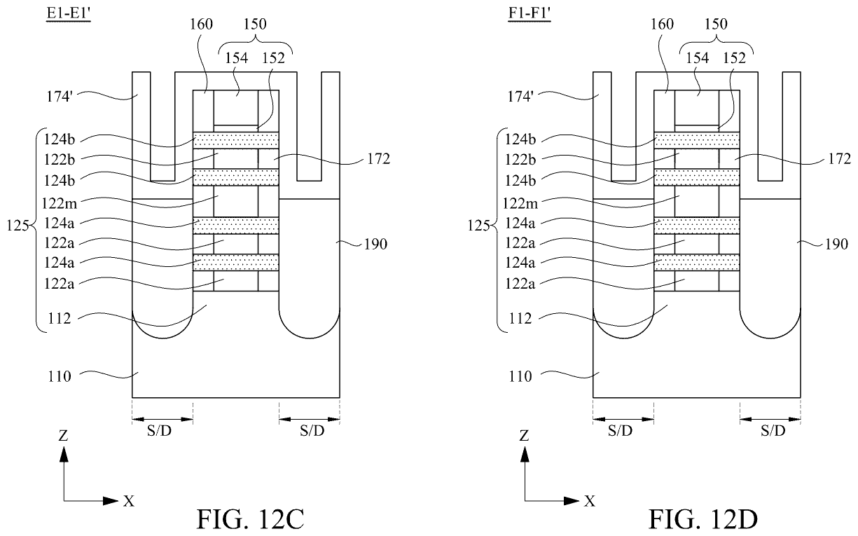

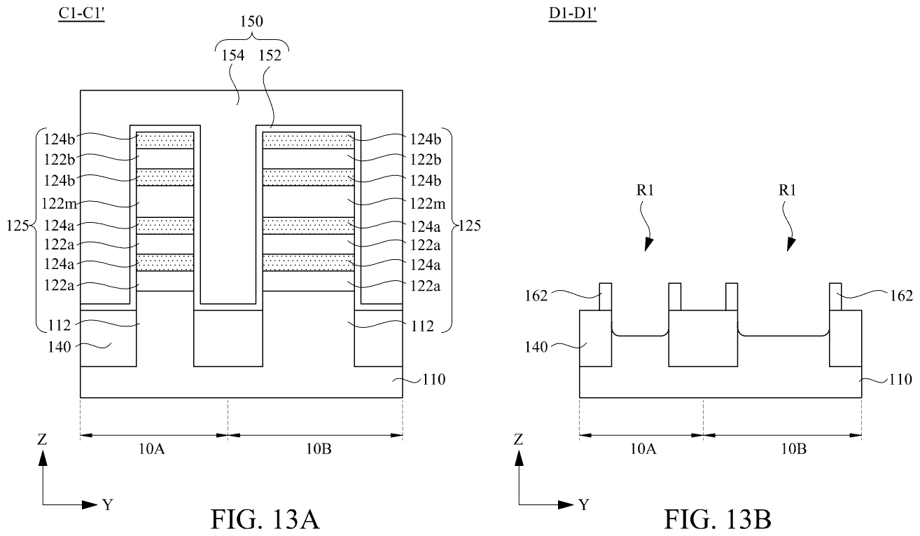

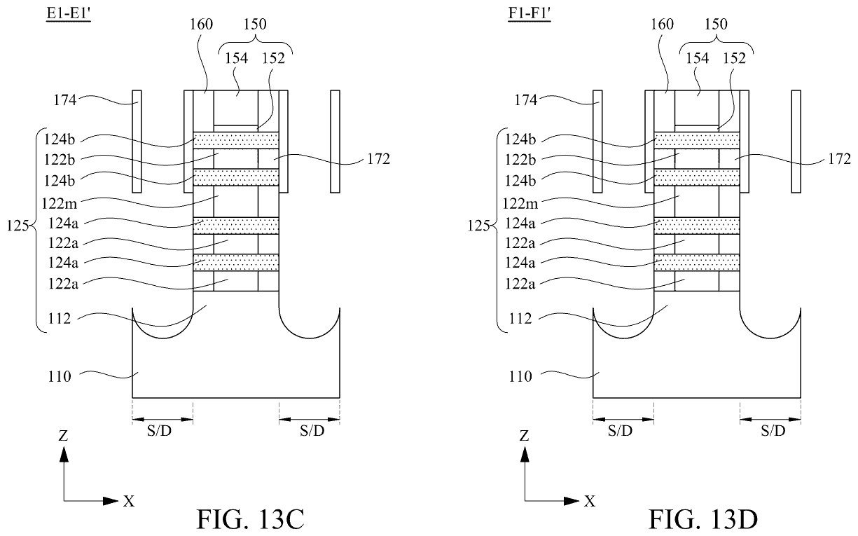

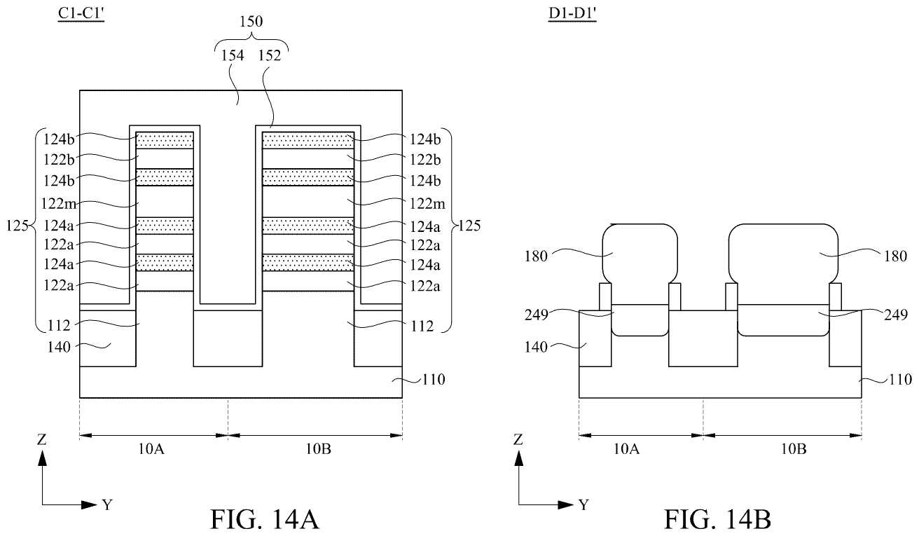

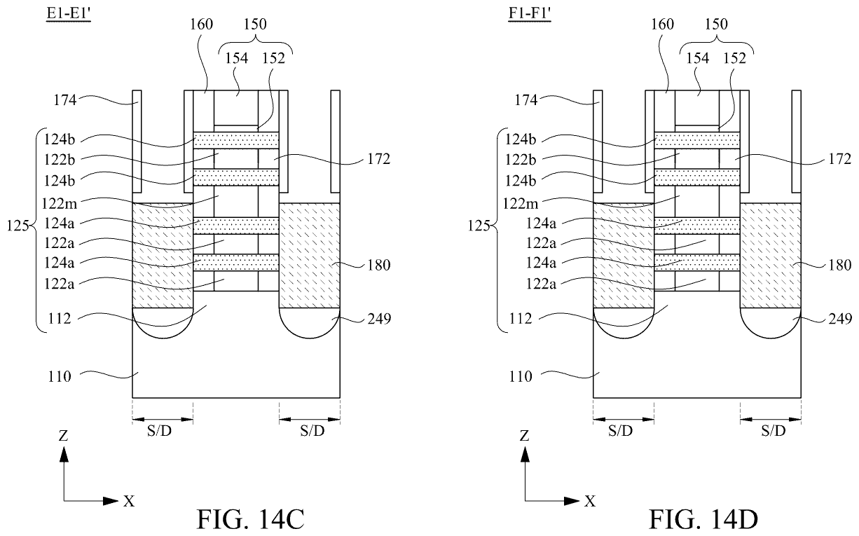

Reference is made to FIGS. 12A-13D. Spacer layers 174, as illustrated in FIGS. 13C and 13D, can be formed to encapsulate the epitaxial layers 124b. This protective layer (i.e., spacer layers 174) can prevent the deposition of additional epitaxial material on the epitaxial layers 124b during the formation of the first source/drain epitaxial structures 180 (see FIGS. 14A-14D), ensuring that the epitaxial growth can be controlled and restricted to designated areas, maintaining the integrity and functionality of the underlying layers.

Specifically, as shown in FIGS. 12A-12D, a sacrificial material 190 can be deposited over the substrate 110 and fills in the recesses R1. By way of example and not limitation, the sacrificial material 190 may be formed of a bottom antireflective coating (BARC). In some embodiments, the sacrificial material 190 may be a low-k dielectric material, such as SiO₂, SiN, SiC, SiON, SiCN, or SiOCN, and may be formed by a suitable deposition method, such as ALD, CVD, or PVD. In some embodiment, the sacrificial material 190 may have a carbon atomic concentration greater than about 3%. In some embodiments, the sacrificial material 190 can be interchangeably referred to as a sacrificial layer, a dummy material, or a dummy layer.

Subsequently, an etching back process can be performed on the sacrificial material 190. The etching back process, which targets the dummy material 190, can be managed by controlling the duration of the process. This controlling is to ensure that the etching can halt at a predetermined level, such that the top surface of the etched-back sacrificial material 190 can align with the epitaxial layer 122m situated between the epitaxial layers 124a and 124b. Halting the etching at the epitaxial layer 122m can ensure that the epitaxial layers 124b are adequately encapsulated by the spacer layers 174. In some embodiments, the target position for the recessed top surface of the sacrificial material 190 can be approximately between the bottom surface of the epitaxial layer 122m and the top surface of the epitaxial layer 122m. In some embodiments, the etching back process can be an anisotropic dry etching process (e.g., a reactive-ion etching (RIE) process or an atomic layer etching (ALE) process), or other forms of plasma processing. That is, the etching back process can be anisotropic, where material is removed more in one direction (e.g., vertical direction) than in others. By way of example and not limitation, the etching back process may implement an etching gas, such as an oxygen-containing gas, a fluorine-containing gas (e.g., CF₄, SF₆, CH₂F₂, CHF₃, CH₃F and/or C₄F₈), a chlorine-containing gas (e.g., Cl₂ and/or BCl₃), a bromine-containing gas (e.g., HBr), an iodine-containing gas, other suitable gases and/or plasmas, and/or combinations thereof.

After etching back of the sacrificial material 190 is completed, the spacer layers 174 can be formed to encapsulate the epitaxial layers 124b. For example, a spacer material layer 174′ is deposited on the substrate 110. The spacer material layer 174′ may be a conformal layer that is subsequently etched back to form sidewall spacers. In the illustrated embodiment, a spacer material layer 174′ is disposed conformally on top of the sacrificial material 190 and top and sidewalls of the dummy gate structure 150 and the fin structure 125. The spacer material layer 174′ may include a dielectric material such as silicon oxide, silicon nitride, silicon carbide, silicon oxynitride, SiCN films, silicon oxycarbide, SiOCN films, and/or combinations thereof. In some embodiments, the spacer material layer 174′ may include multiple layers, such as a first spacer layer and a second spacer layer formed over the first spacer layer.

Subsequently, as shown in FIGS. 13A-13D, an anisotropic etching process is then performed on the deposited spacer material layer 174′ to expose the sacrificial material 190. Portions of the spacer material layer directly above sacrificial material 190, the dummy gate structure 150, and the fin structure 125 may be completely removed by this anisotropic etching process. Portions of the spacer material layer on sidewalls of the dummy gate structure 150 and the fin structure 125 may remain, forming spacer layers 174. Subsequently, an etching process is performed to remove the exposed sacrificial material 190 from the spacer layers 174 to expose the underlying epitaxial layers 124a. In some embodiments, the etching process can be performed through wet etching. For example, the wet etching chemical may include an acid such as HCl, H₂SO₄, H₂CO₃, HF, for the like.

Reference is made to FIGS. 14A-14D. First source/drain epitaxial structures 180 can be formed on the protruding portions 112 and connected to the epitaxial layers 124a. In some embodiments, the first source/drain epitaxial structures 180 may include Ge, Si, GaAs, AlGaAs, SiGe, GaAsP, SiP, or other suitable material. The first source/drain epitaxial structures 180 may be doped by introducing doping species including: p-type dopants, such as boron or BF₂; n-type dopants, such as phosphorus or arsenic; and/or other suitable dopants including combinations thereof. In some embodiments, the first source/drain epitaxial structures 180 can be a p-type including SiGeB and/or GeSnB. In some embodiments, the first source/drain epitaxial structures 180 can be an n-type including SiP. In some embodiments, the first source/drain epitaxial structure 180 can be interchangeably referred to as a source/drain pattern or an epitaxial pattern.

After the formation of the first source/drain epitaxial structures 180, the spacer layers 174 that encapsulate the epitaxial layers 124a are removed. During the removal of the spacer layers 174, the fin spacers 162 may also be completely etched away, potentially due to the etching process being sufficiently aggressive or extensive to consume the fin spacers 162. Concurrently, the isolation structure 140 surrounding the protruding portion 112 can be also subject to this etching. This etching can reduce the vertical extent of the isolation structure 140, lowering its top surface. As a result of this etching process, the position of the top surface of the isolation structure 140 can be decreased enough that the dielectric layer 249, situated beneath or within the isolation structure, becomes exposed. In some embodiments, this etching can result in the top surface of the dielectric layer 249 being positioned higher than the lowered top surface of the isolation structure 140.

In some embodiments, before the first source/drain epitaxial structures 180 are formed, dielectric layers 249 can be formed on bottoms 94b of the recesses R1. In particular, a selective deposition process may include a deposition step to deposit the dielectric material over the substrate 110 and a sputter step to remove the dielectric material deposited on sidewalls of the recesses R1 and an upper surface above the substrate 110, so as to leave the deposited dielectric material on a lower surface above the substrate 110. In some embodiments, the selective deposition process may be performed by an inductively coupled plasma (ICP) tool or a capactitively coupled plasma (CCP) tool. In some embodiments, the deposition gas used in the selective deposition process may include, for example, a silicon source gas, such as silicon tetrachloride gas, SiCl₄, and an oxygen source gas, such as molecular oxygen gas, O₂, in plasma state to form a silicon oxide layer over the substrate 110. In some embodiments, the deposition gas used in the selective deposition process may include, for example, a fluorocarbon (CₓF_{y}) source gas, such as C₄F₆ and/or C₄F₈, and an oxygen source gas, such as molecular oxygen gas, O₂, in plasma state to form a CₓF_{y} layer over the substrate 110. In some embodiments, the deposition gas used in the selective deposition process may include a mixture of BCl₃ and N₂ to deposit boron or boron nitride; a mixture of BCl₃, CH₄ and H₂ to deposit boron carbide. In some embodiments, sputter etching caused by plasmas in the selective deposition process may provide a higher sputter etch rate at the dielectric material on the sidewalls of the recesses R1 and the upper surface above the substrate 110 than on the lower surface above the substrate 110, such that the net effect of the deposition and sputter etching in the selective deposition process leads to the dielectric material remaining on the bottom of the recess R1 and absent on the sidewalls of the recesses R1 and the upper surface above the substrate 110. In some embodiments, the deposition and sputter etching in the selective deposition process may be performed in-situ or ex-situ.

In some embodiments, the dielectric layer 249 can be made of a different material than the inner dielectric spacer 172. In some embodiments, the dielectric layer 249 can be made of a same material as the inner dielectric spacer 172. In some embodiments, the dielectric layer 249 can be made of an oxide-containing material (e.g., SiO₂), a nitrogen-containing material (e.g., SiON, SiN, Si₃N₄), a carbon-containing material (e.g., SiOC, SiCN, SiOCN), the like, or combinations thereof. In some embodiments, the dielectric layer 249 may be made of a material having a dielectric constant greater than about 7.9 (e.g., high dielectric constant (high-k) material). For example, the dielectric layer 249 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

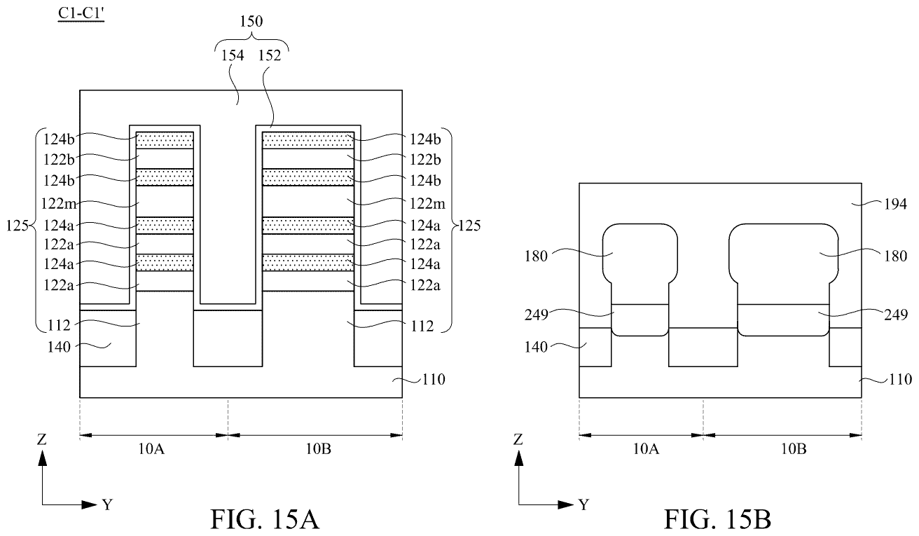

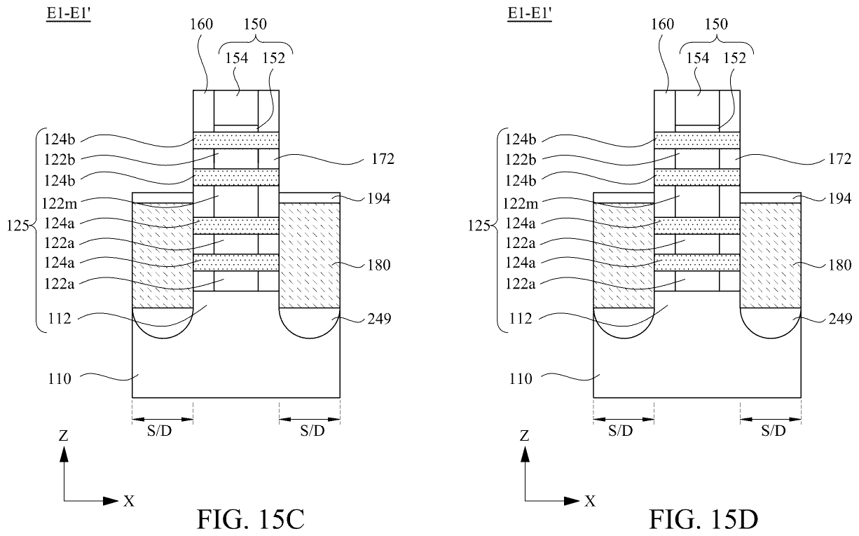

Reference is made to FIGS. 15A-15D. An interlayer dielectric (ILD) layer 194 can be formed over the substrate 110. In some embodiments, a contact etch stop layer (CESL) can be also formed prior to forming the ILD layer 194. In some examples, the CESL can include a silicon nitride layer, silicon oxide layer, a silicon oxynitride layer, and/or other suitable materials having a different etch selectivity than the ILD layer 194. In some embodiments, the CESL and the ILD layer 194 can be collectively referred to as an isolation structure or an epitaxial isolation. In some embodiments, the ILD layer 194 can include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. In some embodiments, the ILD layer 194 may be made of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multi-layer structure including a plurality of dielectric layers.

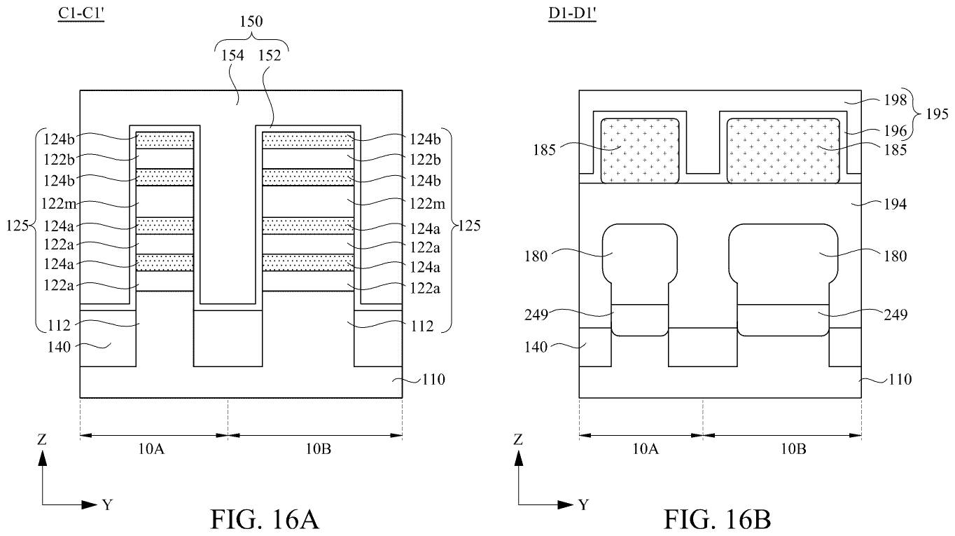

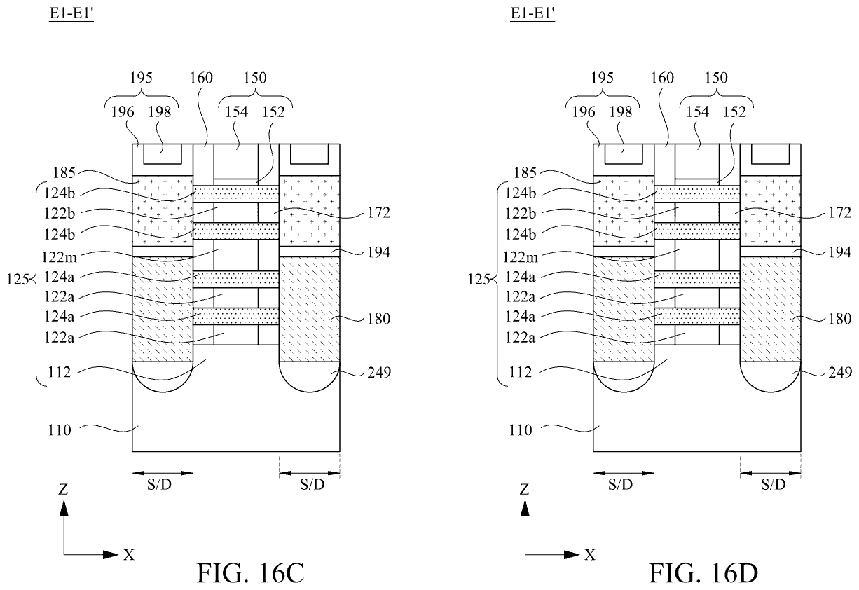

Subsequently, the isolation structures can be recessed, such that the upper portions of the recesses R1 (see FIGS. 9C and 9D) may reappear. Specifically, an etching back process can be performed on the epitaxial isolation including the CESL and the ILD layer 194. The etching back process, which targets the epitaxial isolation, can be managed by controlling the duration of the process. This controlling is to ensure that the etching can halt at a predetermined level, such that the top surface of the etched-back epitaxial isolation can align with the epitaxial layer 122m situated between the epitaxial layers 124a and 124b. Halting the etching at the epitaxial layer 122m can ensure that the second source/drain epitaxial structures 185 (see FIGS. 16C and 16D) can be formed on the epitaxial layers 124b. In some embodiments, the target position for the recessed top surface of the epitaxial isolation can be approximately between the bottom surface of the epitaxial layer 122m and the top surface of the epitaxial layer 122m. In some embodiments, the etching back process can be an anisotropic dry etching process (e.g., a reactive-ion etching (RIE) process or an atomic layer etching (ALE) process), or other forms of plasma processing. That is, the etching back process can be anisotropic, where material is removed more in one direction (e.g., vertical direction) than in others. By way of example and not limitation, the etching back process may implement an etching gas, such as an oxygen-containing gas, a fluorine-containing gas (e.g., CF₄, SF₆, CH₂F₂, CHF₃, CH₃F and/or C₄F₈), a chlorine-containing gas (e.g., Cl₂ and/or BCl₃), a bromine-containing gas (e.g., HBr), an iodine-containing gas, other suitable gases and/or plasmas, and/or combinations thereof.

Reference is made to FIGS. 16A-16D. Second source/drain epitaxial structures 185 can be formed over the ILD layer 194. In some embodiments, the second source/drain epitaxial structures 185 may include Ge, Si, GaAs, AlGaAs, SiGe, GaAsP, SiP, or other suitable material. The second source/drain epitaxial structures 185 may be doped by introducing doping species including: p-type dopants, such as boron or BF₂; n-type dopants, such as phosphorus or arsenic; and/or other suitable dopants including combinations thereof. In some embodiments, the second source/drain epitaxial structures 185 can be a p-type including SiGeB and/or GeSnB. In some embodiments, the second source/drain epitaxial structures 185 can be an n-type including SiP.

In some embodiments, the first source/drain epitaxial structures 180 and the second source/drain epitaxial structures 185 can be made of different materials, such that the first source/drain epitaxial structures 180 can have a first conductivity type, and the second source/drain epitaxial structures 185 can have a second conductivity type opposite to the first conductivity type. By way of example but not limiting the present disclosure, the first source/drain epitaxial structures 180 can include SiP and the second source/drain epitaxial structures 185 can include SiGeB. In some embodiments, the second source/drain epitaxial structure 185 can be interchangeably referred to as a source/drain pattern or an epitaxial pattern. The ILD layer 194 can sandwich between one of the first source/drain epitaxial structures 180 and one of the second source/drain epitaxial structures 185 to electrically isolate the first source/drain epitaxial structure 180 from the second source/drain epitaxial structure 185.

Subsequently, an ILD layer 198 can be formed over the substrate 110. In some embodiments, a CESL 196 can be also formed prior to forming the ILD layer 198. In some examples, the CESL 196 can include a silicon nitride layer, silicon oxide layer, a silicon oxynitride layer, and/or other suitable materials having a different etch selectivity than the ILD layer 198. In some embodiments, the CESL 196 and the ILD layer 198 can be collectively referred to as an isolation structure or an epitaxial isolation 195. In some embodiments, the ILD layer 198 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. After depositing the CESL 196 and the ILD layer 198, a planarization process (e.g., CMP process) may be performed to remove excessive materials of the CESL 196 and the ILD layer 198 overlying the dummy gate structures 150, such that the dummy gate electrode layer 154 can be exposed.

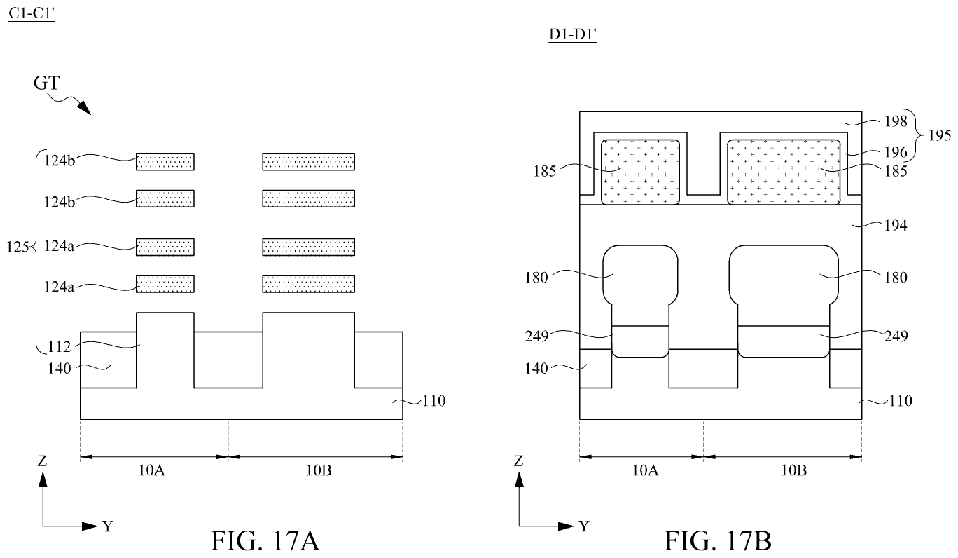

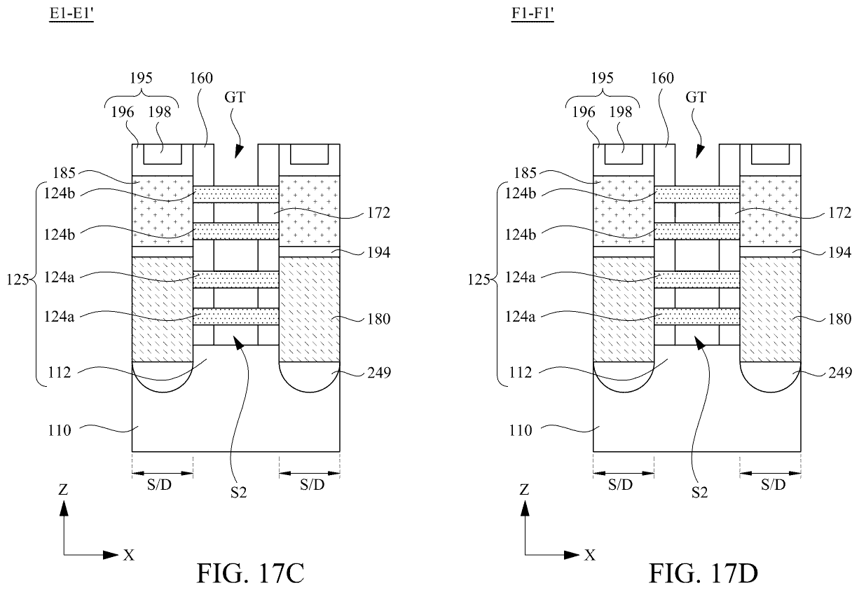

Reference is made to FIGS. 17A-17D. The dummy gate dielectric layer 152 and/or the dummy gate electrode layer 154 as shown in FIGS. 16A-16D is removed, thus resulting in a gate trench GT between the gate spacers 160, with the epitaxial layers 122a and 122b exposed in the gate trench GT. Subsequently, the epitaxial layers 122a and 122b in the gate trench GT are removed, thus forming spaces S2 between neighboring epitaxial layers (i.e., channel layers) 124a and 124b. In some embodiments, the epitaxial layers 124a and 124b can be interchangeably referred to as nanostructure (nanowires, nanoslabs and nanorings, nanosheet, etc., depending on their geometry).

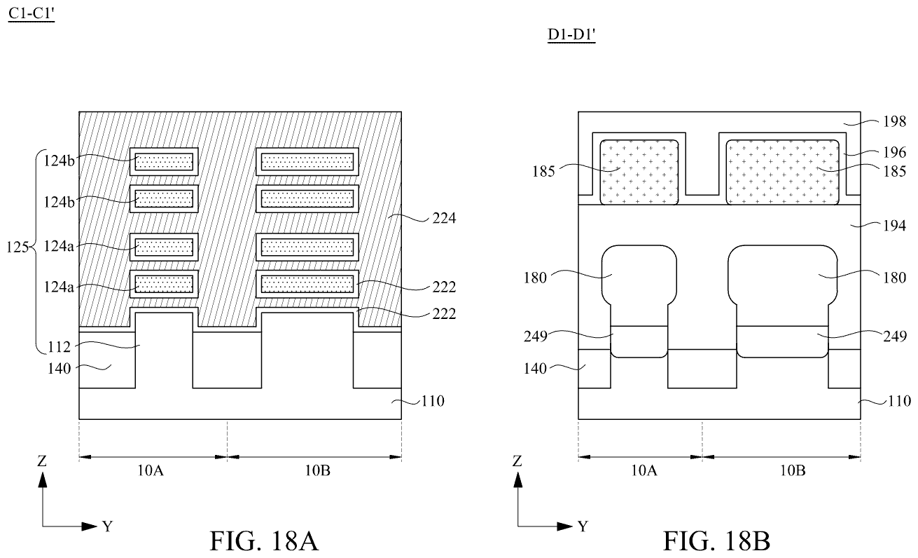

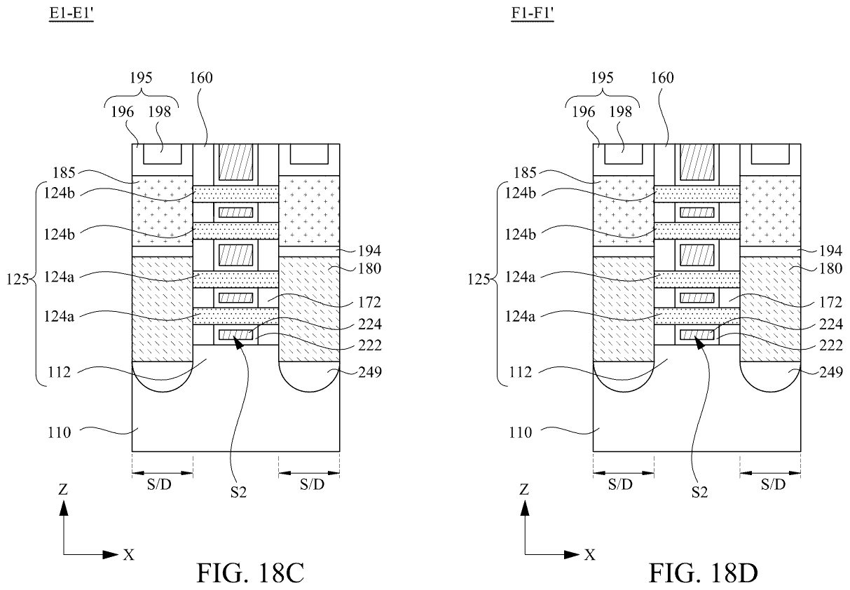

Reference is made to FIGS. 18A-18D. A high-k gate dielectric layer 222 can be formed in the gate trench GT and the spaces S2 to surround each of the epitaxial layers 124a and 124b suspended in the gate trench GT and the spaces S2. Subsequently, a gate electrode layer 224 formed over the high-k gate dielectric layer 222 and filling a remainder of gate trench GT and the spaces S2. In some embodiments, the high-k gate dielectric layer 222 may include dielectric materials having a high dielectric constant (high-k), for example, greater than that of thermal silicon oxide (˜3.9). For example, the high-k dielectric layer 222 may include hafnium oxide (HfO₂). In some embodiments, the gate electrode layer 224 may include a work function metal layer and/or a fill metal formed around the work function metal layer. For an n-type FinFET, the work function metal layer may include one or more n-type work function metals. On the other hand, for a p-type FinFET, the work function metal layer may include one or more p-type work function metals. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. In some embodiments, the high-k gate dielectric layer 222 on the epitaxial layers 124a may have a different thickness than on the epitaxial layers 124b. In some embodiments, the high-k gate dielectric layer 222 on the epitaxial layers 124a can be made of a different material than on the epitaxial layers 124b. In some embodiments, before forming the high-k gate dielectric layer 222, an interfacial layer can be formed in the gate trench GT and the spaces S2 to surround each of the epitaxial layers 124a and 124b. In some embodiments, the interfacial layer (not shown) on the epitaxial layers 124a may have a different thickness than on the epitaxial layers 124b. In some embodiments, the interfacial layer on the epitaxial layers 124a can be made of a different material than on the epitaxial layers 124b.

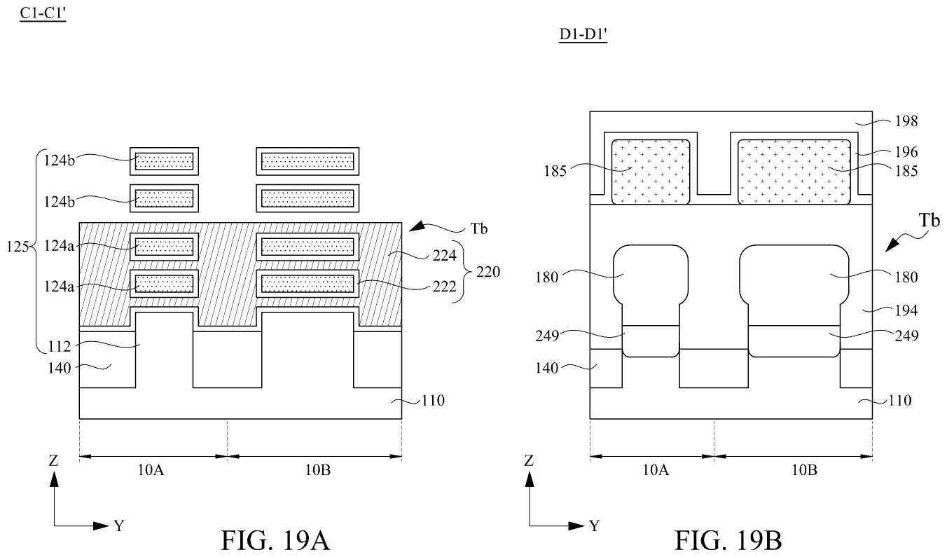

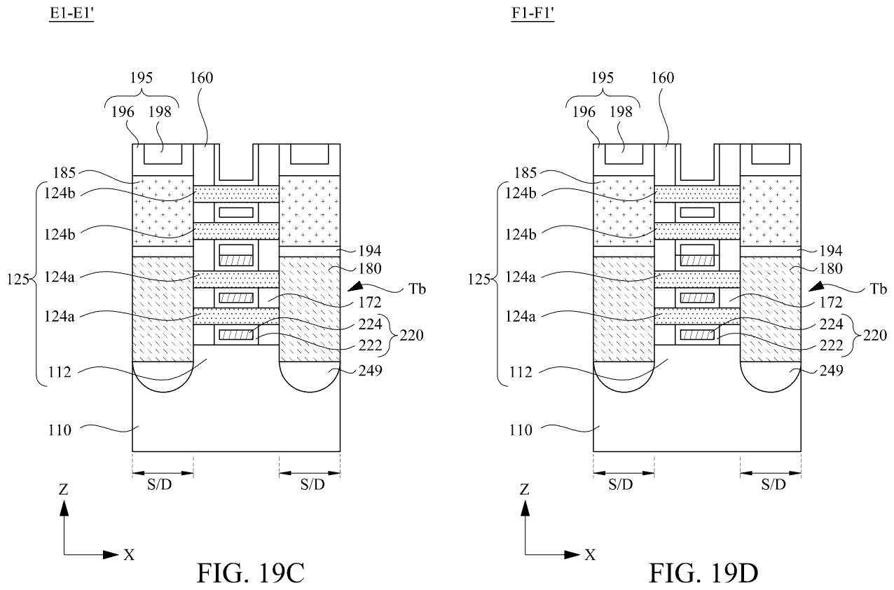

Reference is made to FIGS. 19A-19D. After the formation of the high-k gate dielectric layer 222 and the gate electrode layer 224, the gate electrode layer 224 can be etched back by using an etching process. Specifically, an etching back process can be performed on the gate electrode layer 224 to remove an upper portion of the gate electrode layer 224, such that the upper portions of the gate trenches GT may reappear. In some embodiments, the etching back process can be managed by controlling the duration of the process. This controlling is to ensure that the etching can halt at a predetermined level, such that the top surface of the gate electrode layer 224 can align with the ILD layer 194 situated between the first and second source/drain epitaxial structures 180 and 185. Halting the etching at the ILD layer 194 can ensure that the gate electrode layer 234 (see FIGS. 20A, 20C, and 20D) can be adequately formed on in the remainder of gate trench GT and the spaces S2. In some embodiments, the target position for the recessed top surface of the epitaxial isolation can be approximately between the bottom surface of the ILD layer 194 and the top surface of the ILD layer 194.

In some embodiments, the etching back process can be an anisotropic dry etching process (e.g., a reactive-ion etching (RIE) process or an atomic layer etching (ALE) process), or other forms of plasma processing. That is, the etching back process can be anisotropic, where material is removed more in one direction (e.g., vertical direction) than in others. By way of example and not limitation, the etching back process may implement an etching gas, such as an oxygen-containing gas, a fluorine-containing gas (e.g., CF₄, SF₆, CH₂F₂, CHF₃, CH₃F and/or C₄F₈), a chlorine-containing gas (e.g., Cl₂ and/or BCl₃), a bromine-containing gas (e.g., HBr), an iodine-containing gas, other suitable gases and/or plasmas, and/or combinations thereof.

Therefore, a (metal) gate structure 220 including a lower portion of the high-k gate dielectric layer 222 and the gate electrode layer 224 can be formed in the gate trench GT and the spaces S2 to surround each of the epitaxial layers 124a suspended in the gate trench GT and the spaces S2. In some embodiments, the gate structure 220 can be interchangeably referred to a metal gate, a gate pattern, or a gate strip. The bottom-tier transistors Tb can be formed to each include the channel layers 124a, the first source/drain epitaxial structures 180 on opposite sides of the channel layers 124a and connected to the channel layers 124a, and the gate structure 220 wrapping around the channel layers 124a.

Reference is made to FIGS. 20A-20D. A gate electrode layer 234 can be deposited in the gate trench GT and over the gate electrode layer 226. Specifically, the gate electrode layer 234 can be formed over the high-k gate dielectric layer 222 and filling a remainder of gate trench GT and the spaces S2. In some embodiments, the gate electrode layer 234 may include a work function metal layer and/or a fill metal formed around the work function metal layer. For an n-type FinFET, the work function metal layer may include one or more n-type work function metals. On the other hand, for a p-type FinFET, the work function metal layer may include one or more p-type work function metals. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Therefore, a gate structure 230 including an upper portion of the high-k dielectric layer 222 and the gate electrode layer 234 can be formed within the remainder of the gate trench GT and the spaces S2. In some embodiments, the gate structure 230 can be interchangeably referred to a metal gate, a gate pattern, or a gate strip. The top-tier transistors Tt can be formed over the bottom-tier transistors Tb. The top-tier transistors Tt can be formed to each include the channel layers 124b, the second source/drain epitaxial structures 185 on opposite sides of the channel layers 124b and connected to the channel layers 124b, and a (metal) gate structure 230 wrapping around the channel layers 124b. As such, the semiconductor structure 100a/100b can be formed.

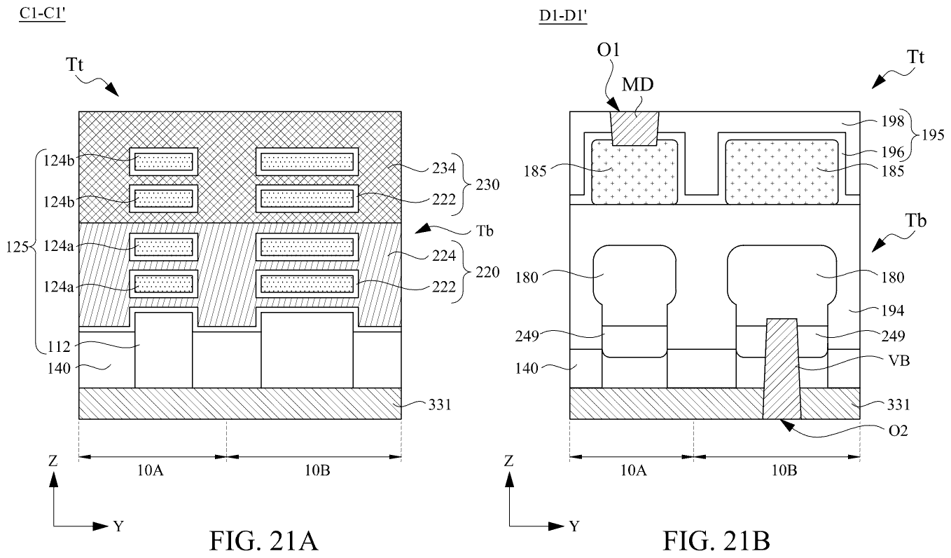

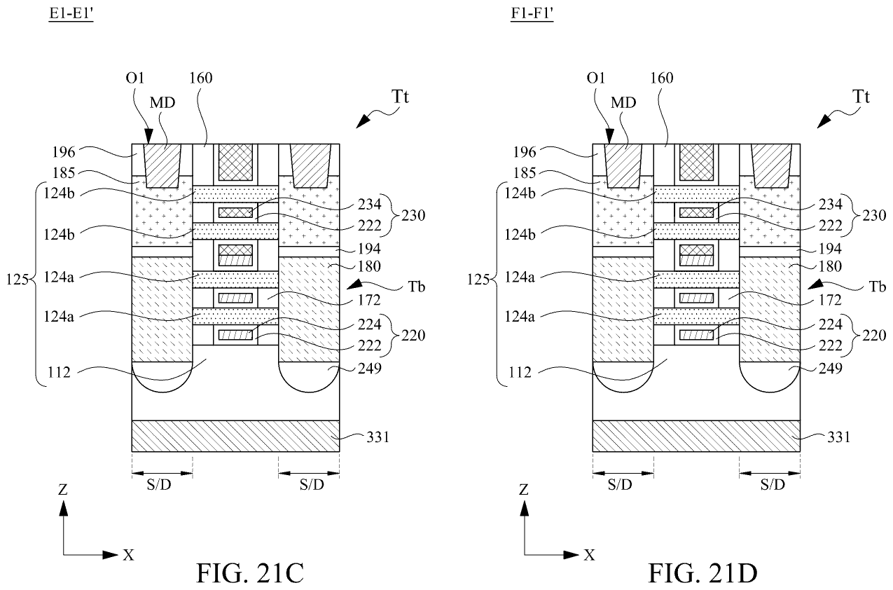

Reference is made to FIGS. 21A-21D. Openings O1 where the source/drain contacts MD will be subsequently formed therein can be formed to extend through the ILD layer 198 and the CESL 196, such that corresponding ones of the second source/drain epitaxial structures 185 can be exposed. In some embodiments, the forming of the openings O1 can be performed by an etching process being an anisotropic dry etching process (e.g., a reactive-ion etching (RIE) process or an atomic layer etching (ALE) process). Before the source/drain contacts MD are formed, metal silicide layers may be selectively formed on the corresponding second source/drain epitaxial structures 185 through the openings O1 by a metal silicidation process. The metal silicidation process is to make a reaction between metal and silicon (or polycrystalline silicon).

Subsequently, the source/drain contacts MD can be formed in remainders of the openings O1 and on the metal silicide layers. In greater detail, a conductive material may be formed by using a metallization process to fill the openings O1. Subsequently, the excess portions of the conductive material are removed, either through etching, chemical mechanical polishing (CMP), or the like, forming the upper surface of the metal-filled opening substantially coplanar with a top surface of the ILD layer 198. The remaining portions of the conductive material in the openings O1 form the source/drain contacts MD. The conductive material may include a low resistivity conductor material selected from the group of conductor materials including, but not limited to, tungsten and tungsten-based alloy. Alternatively, the conductive material may include various materials, such as cobalt, copper, ruthenium, aluminum, gold, silver, another suitable conductive material, or combinations thereof. Subsequently, front-side source/drain vias (not shown) can be formed over the front-side source/drain contacts. Front-side gate vias (not shown) can be formed over a front-side of the gate structure 230. Subsequently, a front-side metal routing (not shown) can be formed over the front-side source/drain vias and the front-side gate vias to electrically connect the front-side source/drain vias and the front-side gate vias.

The dielectric regions (not shown) can be formed in of the gate structure 220 and/or 230. In some embodiments, each dielectric region can be a gate-cut structure for the gate structure 220/230, and the gate-cut structure is formed by a cut metal gate (CMG) process. In some embodiments, the dielectric region can be interchangeably referred to a gate end dielectric or a dielectric structure. In some embodiments, the dielectric region can continuously extend across the gate structures 220/230. In some embodiments, the dielectric region may be formed of or comprise SiO₂, SiOC, SiOCN, or the like, or combinations thereof. In some embodiments, the dielectric region 128 may be made of a nitride-based material, such as Si₃N₄, or a carbon-based material, such as SiOCN, or combinations thereof. In some embodiments, the dielectric region may be made of a material having a dielectric constant greater than about 9 (e.g., high dielectric constant (high-k) material). For example, the dielectric region may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

Subsequently, the substrate 110 can be thinned from the back-side 110b thereof. The substrate 110 can be thinned in a plurality of process operations, for example, CMP, HNA, and/or TMAH etching from the back-side 110b of the substrate 110. A back-side dielectric layer 331 can be formed over the back-side 110b of the substrate 110. In some embodiments, the back-side dielectric layer 331 may be made of dielectric material, such as SiO₂, Si₃N₄, SiON, SiOC, SiOCN base dielectric material, or combinations thereof. In some embodiments, the back-side dielectric layer 331 may be made of an oxide, a nitride-based material, such as Si₃N₄, SiON, or a carbon-based material, such as SiC, SiOC, SiOCN, or combinations thereof. In some embodiments, the back-side dielectric layer 331 may be made of a material having a dielectric constant greater than about 9 (e.g., high dielectric constant (high-k) material). For example, the back-side dielectric layer 331 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

Subsequently, openings O2 (see FIG. 21B) where the back-side source/drain contact VB will be subsequently formed therein can be formed to extend through the back-side dielectric layer 331, the protruding portion 112, and the dielectric layer 249, such that corresponding ones of the first source/drain epitaxial structures 180 can be exposed. In some embodiments, the forming of the openings O2 can be performed by an etching process being an anisotropic dry etching process (e.g., a reactive-ion etching (RIE) process or an atomic layer etching (ALE) process). Before the back-side source/drain contact VB are formed, metal silicide layers may be selectively formed on the corresponding first source/drain epitaxial structures 180 through the openings O2 by a metal silicidation process. The metal silicidation process is to make a reaction between metal and silicon (or polycrystalline silicon).

Subsequently, the back-side source/drain contacts VB can be formed in remainders of the openings O2 and on the metal silicide layers. In greater detail, a conductive material may be formed by using a metallization process to fill the openings O2. Subsequently, the excess portions of the conductive material are removed, either through etching, chemical mechanical polishing (CMP), or the like, forming the upper surface of the metal-filled opening substantially coplanar with a top surface of the back-side dielectric layer 331. The remaining portions of the conductive material in the openings O2 form the back-side source/drain contacts VB. The conductive material may include a low resistivity conductor material selected from the group of conductor materials including, but not limited to, tungsten and tungsten-based alloy. Alternatively, the conductive material may include various materials, such as cobalt, copper, ruthenium, aluminum, gold, silver, another suitable conductive material, or combinations thereof. Subsequently, back-side source/drain vias (not shown) can be formed over the back-side source/drain contacts VB. Subsequently, a back-side metal routing (not shown) can be formed over the back-side source/drain vias.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides small and large cell height devices arranged in a periodic pattern, which in turn leverages the distinct advantages of each cell size. That is, small cells can be used for low power consumption, optimizing energy efficiency across the chip. These smaller cells can be useful in applications of power savings. The larger cells can be used for high-speed performance, providing the processing power for compute-intensive tasks. These larger cells can be useful in applications of requiring rapid data processing and high operational speeds. The periodic placement of these cells can ensure a balanced integration of both power efficiency and speed, allowing for the design of versatile and high-performance semiconductor devices.

In some embodiments, a method includes forming a first cell unit over a substrate, the first cell unit comprising a first bottom-tire transistor and a first top-tier transistor over the first bottom-tire transistor; forming a second cell unit over the substrate, the second cell unit forming a boundary with the first cell unit and comprising a second bottom-tire transistor and a second top-tier transistor over the second bottom-tire transistor, wherein from a top view, a cell height of the second cell unit is greater than a cell height of the first cell unit in a lengthwise direction of a gate structure of the first top-tier transistor. In some embodiments, the cell height of the second cell unit is about 1.1 to 3 times the cell height of the first cell unit. In some embodiments, the method further includes forming a third cell unit over the substrate, the third cell unit forming a boundary with the second cell unit and arranged with the first and second cell units along the lengthwise direction of the gate structure of the first top-tier transistor, wherein from the top view, a cell height of the third cell unit is less than the cell height of the second cell unit. In some embodiments, the cell height of the third cell unit is substantially the same as the cell height of the first cell unit. In some embodiments, the method further includes forming a third cell unit over the substrate, the third cell unit forming a boundary with the second cell unit and arranged with the first and second cell units along the lengthwise direction of the gate structure of the first top-tier transistor, wherein from the top view, a cell height of the third cell unit is substantially the same as a cell height of the second cell unit. In some embodiments, the cell height of the third cell unit is greater than the cell height of the first cell unit. In some embodiments, the second cell unit is arranged with the first cell unit along a direction perpendicular to the lengthwise direction of the gate structure of the first top-tier transistor. In some embodiments, the method further includes forming a plurality of continuous poly on oxide definition patterns over the substrate and between the first and second cell units. In some embodiments, the method further includes forming a third cell unit over the substrate, the third cell unit forming a boundary with the second cell unit and arranged with the first cell unit along the lengthwise direction of the gate structure of the first top-tier transistor, wherein from the top view, the cell height of the second cell unit is greater than a cell height of the third cell unit. In some embodiments, the first and second bottom-tire transistor are of a first conductivity type, and the first and second top-tier transistor are of a second conductivity type opposite to the first conductivity type.

In some embodiments, a method includes forming a first semiconductive nanostructure over a substrate, a second semiconductive nanostructure over the substrate and laterally adjacent to the first semiconductive nanostructure, a third semiconductive nanostructure over the first semiconductive nanostructure, and a fourth semiconductive nanostructure over the second semiconductive nanostructure; forming first epitaxial structures on opposite sides of the first semiconductive nanostructure, second epitaxial structures on opposite sides of the second semiconductive nanostructure, third epitaxial structures on opposite sides of the third semiconductive nanostructure, and fourth epitaxial structures on opposite sides of the fourth semiconductive nanostructure; forming a first gate wrapping around the first semiconductive nanostructure, a second gate wrapping around the second semiconductive nanostructure, a third gate wrapping around the third semiconductive nanostructure, and a fourth gate wrapping around the fourth semiconductive nanostructure, in which a dimension of the first semiconductive nanostructure in a lengthwise direction of the first gate is different than a dimension of the second semiconductive nanostructure in the lengthwise direction of the first gate. In some embodiments, a dimension of one of the first epitaxial structures in the lengthwise direction of the first gate is different than a dimension of one of the third epitaxial structures in the lengthwise direction of the first gate. In some embodiments, the method further includes before forming the first, second, third, and fourth epitaxial structures, forming first and second bottom isolation dielectrics over the substrate, wherein after forming the first, second, third, and fourth epitaxial structures, the first bottom isolation dielectric interposes between one of the first epitaxial structures and the substrate, and the second bottom isolation dielectric interposes between one of the second epitaxial structures and the substrate. In some embodiments, a vertical dimension of the third semiconductive nanostructure is different than a vertical dimension of the first semiconductive nanostructure. In some embodiments, the fourth semiconductive nanostructure is made of a different material than the second semiconductive nanostructure.

In some embodiments, a semiconductor structure includes a substrate, a first transistor, a second transistor, a third transistor, and a fourth transistor. The first transistor is over the substrate and is of a first cell unit. The first transistor includes first nanostructures and a first gate structure surrounding each of the first nanostructures. The second transistor is over the first transistor and is of the first cell unit. The third transistor is laterally adjacent to the first transistor and is of a second cell unit. The fourth transistor is over the third transistor and is of the second cell unit. The fourth transistor includes second nanostructures and a second gate structure surrounding each of the second nanostructures. From a top view, a dimension of one of the first nanostructures in a lengthwise direction of the first gate structure is less than a dimension of one of the second nanostructures in the lengthwise direction of the first gate structure. In some embodiments, the third transistor comprises third nanostructures and a third gate structure surrounding each of the third nanostructures, and from the top view, the dimension of the one of the first nanostructures is less than a dimension of one of the third nanostructures in the lengthwise direction of the first gate structure. In some embodiments, a number of the third nanostructures is different than a number of the second nanostructures. In some embodiments, a distance between adjacent two of the third nanostructures is different than a distance between adjacent two of the second nanostructures. In some embodiments, from the top view, a length of the first gate structure is less than a length of the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first cell unit over a substrate, the first cell unit comprising a first bottom-tire transistor and a first top-tier transistor over the first bottom-tire transistor; and
forming a second cell unit over the substrate, the second cell unit forming a boundary with the first cell unit and comprising a second bottom-tire transistor and a second top-tier transistor over the second bottom-tire transistor, wherein from a top view, a cell height of the second cell unit is greater than a cell height of the first cell unit in a lengthwise direction of a gate structure of the first top-tier transistor.

2. The method of claim 1, wherein the cell height of the second cell unit is about 1.1 to 3 times the cell height of the first cell unit.

3. The method of claim 1, further comprising:
forming a third cell unit over the substrate, the third cell unit forming a boundary with the second cell unit and arranged with the first and second cell units along the lengthwise direction of the gate structure of the first top-tier transistor, wherein from the top view, a cell height of the third cell unit is less than the cell height of the second cell unit.

4. The method of claim 3, wherein the cell height of the third cell unit is substantially the same as the cell height of the first cell unit.

5. The method of claim 1, further comprising:
forming a third cell unit over the substrate, the third cell unit forming a boundary with the second cell unit and arranged with the first and second cell units along the lengthwise direction of the gate structure of the first top-tier transistor, wherein from the top view, a cell height of the third cell unit is substantially the same as a cell height of the second cell unit.

6. The method of claim 5, wherein the cell height of the third cell unit is greater than the cell height of the first cell unit.

7. The method of claim 1, wherein the second cell unit is arranged with the first cell unit along a direction perpendicular to the lengthwise direction of the gate structure of the first top-tier transistor.

8. The method of claim 7, further comprising:
forming a plurality of continuous poly on oxide definition patterns over the substrate and between the first and second cell units.

9. The method of claim 7, further comprising:
forming a third cell unit over the substrate, the third cell unit forming a boundary with the second cell unit and arranged with the first cell unit along the lengthwise direction of the gate structure of the first top-tier transistor, wherein from the top view, the cell height of the second cell unit is greater than a cell height of the third cell unit.

10. The method of claim 1, wherein the first and second bottom-tire transistor are of a first conductivity type, and the first and second top-tier transistor are of a second conductivity type opposite to the first conductivity type.

11. A method, comprising:
forming a first semiconductive nanostructure over a substrate, a second semiconductive nanostructure over the substrate and laterally adjacent to the first semiconductive nanostructure, a third semiconductive nanostructure over the first semiconductive nanostructure, and a fourth semiconductive nanostructure over the second semiconductive nanostructure;
forming first epitaxial structures on opposite sides of the first semiconductive nanostructure, second epitaxial structures on opposite sides of the second semiconductive nanostructure, third epitaxial structures on opposite sides of the third semiconductive nanostructure, and fourth epitaxial structures on opposite sides of the fourth semiconductive nanostructure; and
forming a first gate wrapping around the first semiconductive nanostructure, a second gate wrapping around the second semiconductive nanostructure, a third gate wrapping around the third semiconductive nanostructure, and a fourth gate wrapping around the fourth semiconductive nanostructure,
wherein a dimension of the first semiconductive nanostructure in a lengthwise direction of the first gate is different than a dimension of the second semiconductive nanostructure in the lengthwise direction of the first gate.

12. The method of claim 11, wherein a dimension of one of the first epitaxial structures in the lengthwise direction of the first gate is different than a dimension of one of the third epitaxial structures in the lengthwise direction of the first gate.

13. The method of claim 11, further comprising:
before forming the first, second, third, and fourth epitaxial structures, forming first and second bottom isolation dielectrics over the substrate, wherein after forming the first, second, third, and fourth epitaxial structures, the first bottom isolation dielectric interposes between one of the first epitaxial structures and the substrate, and the second bottom isolation dielectric interposes between one of the second epitaxial structures and the substrate.

14. The method of claim 11, wherein a vertical dimension of the third semiconductive nanostructure is different than a vertical dimension of the first semiconductive nanostructure.

15. The method of claim 11, wherein the fourth semiconductive nanostructure is made of a different material than the second semiconductive nanostructure.

16. A semiconductor structure, comprising:
a first transistor over a substrate and being of a first cell unit, the first transistor comprising:
first nanostructures; and
a first gate structure surrounding each of the first nanostructures; and
a second transistor over the first transistor and being of the first cell unit;
a third transistor laterally adjacent to the first transistor and being of a second cell unit; and
a fourth transistor over the third transistor and being of the second cell unit, the fourth transistor comprising:
second nanostructures; and
a second gate structure surrounding each of the second nanostructures, wherein from a top view, a dimension of one of the first nanostructures in a lengthwise direction of the first gate structure is less than a dimension of one of the second nanostructures in the lengthwise direction of the first gate structure.

17. The semiconductor structure of claim 16, wherein the third transistor comprises third nanostructures and a third gate structure surrounding each of the third nanostructures, and from the top view, the dimension of the one of the first nanostructures is less than a dimension of one of the third nanostructures in the lengthwise direction of the first gate structure.

18. The semiconductor structure of claim 17, wherein a number of the third nanostructures is different than a number of the second nanostructures.

19. The semiconductor structure of claim 17, wherein a distance between adjacent two of the third nanostructures is different than a distance between adjacent two of the second nanostructures.

20. The semiconductor structure of claim 16, wherein from the top view, a length of the first gate structure is less than a length of the second gate structure.
